(19) United States
(12) Patent Application Publication
(10) Pub. No.: US 2026/0136546 A1
(43) Pub. Date: May 14, 2026

(54) SEMICONDUCTOR DEVICE INCLUDING GUARD RING

(71) Applicant: SK hynix Inc., Gyeonggi-do (KR)

(72) Inventor: Heon Yong CHANG, Gyeonggi-do (KR)

(21) Appl. No.: 19/074,442

(22) Filed: Mar. 10, 2025

(30) Foreign Application Priority Data
Nov. 13, 2024 (KR) 10-2024-0161165

(51) Int. Cl. H10B 12/00

(52) U.S. Cl. CPC H10B 12/50; H10B 12/02; H10B 12/315

(57) ABSTRACT

A semiconductor device may include a first circuit structure and a second circuit structure bonded onto the first circuit structure. The first circuit structure may include a first active region and a first guard ring region. The second circuit structure may include a second active region and a second guard ring region. The semiconductor device may further include a first upper contact plug disposed in the first active region and the second active region, passing through an interface between the first circuit structure and the second circuit structure, and a first upper contact guard ring disposed in the first guard ring region and the second guard ring region, passing through the interface. The second circuit structure may include a bit line in the second active region, and a bit guard ring disposed in the second guard ring region at substantially the same level as the bit line.

### CROSS-REFERENCE TO RELATED APPLICATION

The present application claims priority under 35 U.S.C. § 119(a) to Korean Patent Application No. 10-2024-0161165 filed on Nov. 13, 2024, which is incorporated herein by reference in its entirety.

### BACKGROUND

### 1. Technical Field

Embodiments of the present disclosure relate generally to semiconductor technology and in particular to a semiconductor device including a guard ring and a method of forming the same.

### 2. Related Art

In response to the high integration of semiconductor devices, a technology of bonding a second wafer including memory cells onto a first wafer including a peripheral circuit is being attempted. The second wafer should be bonded onto the first wafer with adequate strength. The memory cells should be electrically connected to the peripheral circuit.

### SUMMARY

Embodiments of the present disclosure are directed to providing a semiconductor device including a guard ring and a method of forming the same.

The embodiments of the present disclosure are not limited to the features or operations specifically mentioned in this specification, and other features or operations not mentioned may be clearly understood by those skilled in the art from the description below.

In an embodiment of the present disclosure, a semiconductor device may include a first circuit structure and a second circuit structure bonded together, the first circuit structure including a first active region and a first guard ring region; and the second circuit structure including a second active region and a second guard ring region; a first upper contact plug disposed in the first active region and the second active region, and passing through an interface between the first circuit structure and the second circuit structure; and a first upper contact guard ring disposed in the first guard ring region and the second guard ring region, and passing through the interface. The second circuit structure may include a bit line in the second active region; and a bit guard ring disposed in the second guard ring region and at substantially the same level as the bit line.

In an embodiment of the present disclosure, a semiconductor device may include a substrate disposed in a first active region and a first guard ring region; a lower insulating layer disposed on the substrate; a lower gate electrode disposed in the lower insulating layer; a lower wiring disposed in the lower insulating layer in the first active region; a lower wiring guard ring disposed in the lower insulating layer in the first guard ring region; a lower insulating bonding layer disposed on the lower insulating layer; an upper insulating bonding layer bonded onto the lower insulating bonding layer; a first upper insulating layer on the upper insulating bonding layer; a second upper insulating layer disposed between the upper insulating bonding layer and the first upper insulating layer; a bit line disposed in the second upper insulating layer in a second active region; a bit guard ring disposed in the second upper insulating layer in a second guard ring region, the bit guard ring being disposed at substantially the same level as the bit line; a first upper contact plug passing through the first upper insulating layer, the second upper insulating layer, the upper insulating bonding layer, the lower insulating bonding layer and the lower insulating layer to contact the lower wiring; a first upper contact guard ring passing through the first upper insulating layer, the second upper insulating layer, the upper insulating bonding layer, the lower insulating bonding layer and the lower insulating layer to contact the lower wiring guard ring; an upper channel disposed in the first upper insulating layer in the second active region, and disposed on the bit line; an upper gate electrode disposed in the first upper insulating layer in the second active region, and spaced apart from the upper channel; a landing pad disposed on the first upper insulating layer, and connected to the upper channel; a lower electrode disposed on the landing pad; a capacitor dielectric layer disposed on the lower electrode; and an upper electrode disposed on the capacitor dielectric layer.

In an embodiment of the present disclosure, a semiconductor device may include a first circuit structure including a first active region and a first guard ring region; and a second circuit structure including a second active region and a second guard ring region, wherein the second circuit structure is bonded onto the first circuit structure. The second circuit structure may include a bit line in the second active region; and a bit guard ring disposed in the second guard ring region and at substantially the same level as the bit line.

According to embodiments of the present disclosure, it is possible to provide a semiconductor device including a guard ring and a method of forming the same.

The effects of the embodiments of the present invention disclosure are not limited to the effects mentioned above, and other effects not mentioned will be understood by those skilled in the art from the description and the claims.

### BRIEF DESCRIPTION OF THE DRAWINGS

The embodiments of the present disclosure will be more fully understood from the detailed description and the accompanying drawings, which are provided for illustration only and are not intended to limit the embodiments.

FIG. 1 is a cross-sectional view of a semiconductor device according to embodiments of the present disclosure.

FIG. 2 shows partial views illustrating parts of FIG. 1.

FIG. 3 is a plan view of the semiconductor device according to embodiments of the present disclosure.

FIG. 4 and FIG. 5 are cross-sectional views of semiconductor devices according to embodiments of the present disclosure.

FIG. 6 to FIG. 25 are cross-sectional views for explaining methods of forming a semiconductor device according to embodiments of the present disclosure.

### DETAILED DESCRIPTION

Embodiments of the present disclosure are described in detail with reference to the accompanying drawings. Specific structural or functional descriptions of the embodiments are provided as examples to describe concepts that are disclosed in the present disclosure. Embodiments in accordance with the technical concepts of the present disclosure may be carried out in various forms, and the scope of the present disclosure is not limited to the embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

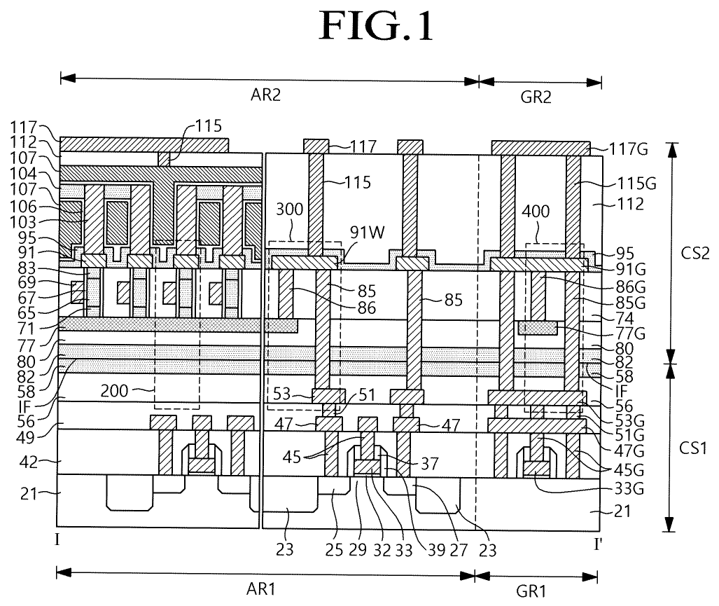

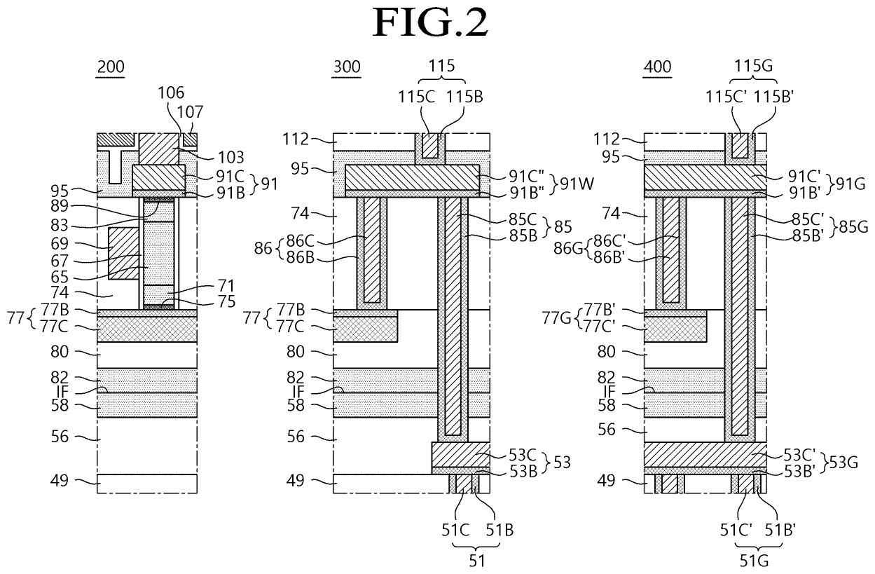

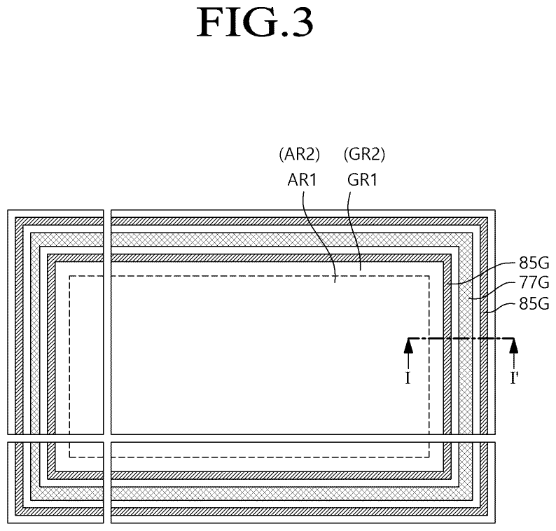

FIG. 1 is a cross-sectional view of a semiconductor device according to embodiments of the present disclosure. FIG. 2 shows partial views illustrating parts 200, 300 and 400 of FIG. 1. FIG. 3 is a plan view of the semiconductor device according to embodiments of the present disclosure. In an embodiment, FIG. 1 may be a cross-sectional view taken along a section line I-I′ of FIG. 3. In an embodiment, the semiconductor device according to embodiments of the present disclosure may include a volatile memory device such as DRAM.

Referring to FIG. 1, the semiconductor device according to embodiments of the present disclosure may include a first circuit structure CS1 that includes a first active region AR1 and a first guard ring region GR1. The semiconductor device may further include a second circuit structure CS2 that is bonded onto the first circuit structure CS1, a first upper contact plug 85, and a first upper contact guard ring 85G. The first guard ring region GR1 may be continuous to the side surface of the first active region AR1. The second circuit structure CS2 may include a second active region AR2 and a second guard ring region GR2. The second active region AR2 may overlap with first active region AR1. The second guard ring region GR2 may overlap with the first guard ring region GR1. The second guard ring region GR2 may be continuous to the side surface of the second active region AR2. The first upper contact plug 85 may extend into the first circuit structure CS1 and the second circuit structure CS2 by passing through an interface IF between the first circuit structure CS1 and the second circuit structure CS2. The first upper contact plug 85 may be disposed in the first active region AR1 and the second active region AR2. The first upper contact guard ring 85G may extend into the first circuit structure CS1 and the second circuit structure CS2 by passing through the interface IF between the first circuit structure CS1 and the second circuit structure CS2. The first upper contact guard ring 85G may be disposed in the first guard ring region GR1 and the second guard ring region GR2.

The first circuit structure CS1 may include a first substrate 21, an isolation layer 23, a lower source region 25, a lower drain region 27, a lower channel region 29, a lower gate insulating layer 32, a lower gate electrode 33, a lower gate guard ring 33G, a gate capping layer 37, a gate spacer 39, a first lower insulating layer 42, a first lower contact plug 45, a first lower contact guard ring 45G, a first lower wiring 47, a first lower wiring guard ring 47G, a second lower insulating layer 49, a second lower contact plug 51, a second lower contact guard ring 51G, a second lower wiring 53, a second lower wiring guard ring 53G, a third lower insulating layer 56, and a lower insulating bonding layer 58.

The second circuit structure CS2 may include an upper channel 65, an upper gate insulating layer 67, an upper gate electrode 69, an upper source region 71, a first upper insulating layer 74, a bit line 77, a bit guard ring 77G, a second upper insulating layer 80, an upper insulating bonding layer 82, an upper drain region 83, a second upper contact plug 86, a second upper contact guard ring 86G, a landing pad 91, a first upper wiring 91W, a first upper wiring guard ring 91G, an etch stop layer 95, a lower electrode 103, a support 104, a capacitor dielectric layer 106, an upper electrode 107, a third upper insulating layer 112, a third upper contact plug 115, a third upper contact guard ring 115G, a second upper wiring 117, and a second upper wiring guard ring 117G.

Referring to FIG. 2, the second lower contact plug 51 and the second lower contact guard ring 51G may include second lower contact barrier layers 51B and 51B′, respectively. The second lower contact plug 51 and the second lower contact guard ring 51G may also include second lower contact conductive layers 51C and 51C′, respectively. The second lower wiring 53 and the second lower wiring guard ring 53G may include second lower wiring barrier layers 53B and 53B′, respectively. The second lower wiring 53 and the second lower wiring guard ring 53G may also include second lower wiring conductive layers 53C and 53C′. The second lower wiring conductive layers 53C and 53C′ may be disposed on the second lower wiring barrier layers 53B and 53B′, respectively. The first silicide layer 75 may be disposed between the upper source region 71 and the bit line 77.

The bit line 77 and the bit guard ring 77G may include the bit barrier layers 77B and 77B′, respectively. The bit line 77 and the bit guard ring 77G may also include the bit conductive layers 77C and 77C′, respectively. The bit barrier layers 77B and 77B′ may be disposed on the bit conductive layers 77C and 77C′, respectively. The first upper contact plug 85 and the first upper contact guard ring 85G may include first upper contact barrier layers 85B and 85B′, respectively. The first upper contact plug 85 and the first upper contact guard ring 85G may also include first upper contact conductive layers 85C and 85C′, respectively. The second upper contact plug 86 and the second upper contact guard ring 86G may include second upper contact barrier layers 86B and 86B′, respectively. The second upper contact plug 86 and the second upper contact guard ring 86G may also include second upper contact conductive layers 86C and 86C′, respectively. A second silicide layer 89 may be disposed between the upper drain region 83 and the landing pad 91.

The landing pad 91, the first upper wiring guard ring 91G, and the first upper wiring 91W may include landing pad barrier layers 91B, 91B′ and 91B″, respectively. The landing pad 91, the first upper wiring guard ring 91G, and the first upper wiring 91W may also include landing pad conductive layers 91C, 91C′ and 91C″, respectively. The landing pad conductive layers 91C, 91C′ and 91C″ may be disposed on the landing pad barrier layers 91B, 91B′ and 91B″, respectively. The third upper contact plug 115 and the third upper contact guard ring 115G may include third upper contact barrier layers 115B and 115B′, respectively. The third upper contact plug 115 and the third upper contact guard ring 115G may also include third upper contact conductive layers 115C and 115C′.

Referring to FIG. 3, the semiconductor device according to embodiments of the present disclosure may include the first and second active regions AR1 and AR2 and the first and second guard ring regions GR1 and GR2. In an embodiment, the first guard ring region GR1 may surround the edge of the first active region AR1. The second active region AR2 may overlap with the first active region AR1. The second guard ring region GR2 may overlap with the first guard ring region GR1. The second guard ring region GR2 may surround the edge of the second active region AR2. The bit guard ring 77G may be disposed in the second guard ring region GR2. The first upper contact guard ring 85G may be disposed in the first guard ring region GR1 and the second guard ring region GR2. The bit guard ring 77G may surround the edge of the second active region AR2. The first upper contact guard ring 85G may surround the edges of the first and second active regions AR1 and AR2.

Referring again to FIG. 1, FIG. 2, and FIG. 3, the first substrate 21 may be disposed in the first active region AR1 and the first guard ring region GR1. The first substrate 21 may extend from the first active region AR1 to the first guard ring region GR1. The isolation layer 23, the lower source region 25, the lower drain region 27 and the lower channel region 29 may be disposed in the first active region AR1 of the first substrate 21. The isolation layer 23 may serve to delimit the lower source region 25, the lower drain region 27 and the lower channel region 29. The lower source region 25 and the lower drain region 27 may be spaced apart from each other. In an embodiment, each of the lower source region 25 and the lower drain region 27 may extend from the upper surface of the first substrate 21 to a predetermined depth. The lower channel region 29 may be delimited in the first substrate 21 between the lower source region 25 and the lower drain region 27.

The first lower insulating layer 42, the second lower insulating layer 49, the third lower insulating layer 56 and the lower insulating bonding layer 58 may be sequentially stacked according to the recited order over the first substrate 21. Each of the first to third lower insulating layers 42, 49, and 56, and the lower insulating bonding layer 58 may extend from the first active region AR1 to the first guard ring region GR1. The first lower insulating layer 42 may cover the isolation layer 23, the lower source region 25, the lower drain region 27 and the lower channel region 29.

The lower gate insulating layer 32, the lower gate electrode 33 and the gate capping layer 37 may be sequentially stacked over the lower channel region 29 in the recited order, with the lower gate insulating layer 32 disposed on the lower channel region 29. The gate spacer 39 may be disposed on the side surfaces of the lower gate electrode 33 and the gate capping layer 37. The first lower insulating layer 42 may cover the lower gate insulating layer 32, the lower gate electrode 33, the gate capping layer 37 and the gate spacer 39. The lower gate insulating layer 32, the lower gate electrode 33, the gate capping layer 37 and the gate spacer 39 may be disposed in the first active region AR1.

The lower source region 25, the lower drain region 27, the lower channel region 29, the lower gate insulating layer 32 and the lower gate electrode 33 may constitute a lower transistor. A plurality of lower transistors may be disposed in the first active region AR1. The first circuit structure CS1 may include various types of active/passive elements such as lower transistors. The first circuit structure CS1 may include a peripheral circuit. The lower transistor may correspond to a part of the peripheral circuit. In an embodiment, a lower transistor may include a planar transistor, a recess channel transistor, a vertical transistor, a fin field effect transistor (finFET), a gate all around (GAA) transistor, a multi-bridge channel transistor, or a combination thereof.

The lower gate guard ring 33G may be disposed on the first substrate 21 in the first guard ring region GR1. The first lower insulating layer 42 may cover the lower gate guard ring 33G. The lower gate guard ring 33G may include the same material and may be formed simultaneously with the gate electrode 33. The lower gate guard ring 33G may have substantially the same thickness as the gate electrode 33. The lower gate guard ring 33G may be disposed at substantially the same level as the gate electrode 33. The lowermost surface of the lower gate guard ring 33G may be disposed at substantially the same level as the lowermost surface of the gate electrode 33. The uppermost surface of the lower gate guard ring 33G may be disposed at substantially the same level as the uppermost surface of the gate electrode 33. In an embodiment, components similar to the lower gate insulating layer 32, the gate capping layer 37 and the gate spacer 39 may be additionally disposed around the lower gate guard ring 33G, but are omitted for the sake of simplicity in description.

A plurality of first lower contact plugs 45 may be disposed in the first active region AR1. The first lower contact plug 45 may pass through the first lower insulating layer 42 and contact the lower source region 25, the lower drain region 27 or the lower gate electrode 33. A plurality of first lower contact guard rings 45G may be disposed in the first guard ring region GR1. The first lower contact guard ring 45G may pass through the first lower insulating layer 42 and contact the lower gate guard ring 33G or the first substrate 21.

The first lower contact guard ring 45G may include the same material and may be formed simultaneously with the first lower contact plug 45. The first lower contact guard ring 45G may have substantially the same thickness as the first lower contact plug 45. The first lower contact guard ring 45G may be disposed at substantially the same level as the first lower contact plug 45. The lowermost surface of the first lower contact guard ring 45G may be disposed at substantially the same level as the lowermost surface of the first lower contact plug 45. The uppermost surface of the first lower contact guard ring 45G may be disposed at substantially the same level as the uppermost surface of the first lower contact plug 45.

A plurality of first lower wirings 47 may be disposed on the first lower insulating layer 42 in the first active region AR1. The first lower wirings 47 may contact corresponding first lower contact plugs 45. The second lower insulating layer 49 may cover the first lower wirings 47. The first lower wiring guard ring 47G may be disposed on the first lower insulating layer 42 in the first guard ring region GR1. The first lower wiring guard ring 47G may contact the first lower contact guard ring 45G. The second lower insulating layer 49 may cover the first lower wiring guard ring 47G.

The first lower wiring guard ring 47G may include the same material and may be formed simultaneously with the first lower wiring 47. The first lower wiring guard ring 47G may have substantially the same thickness as the first lower wiring 47. The first lower wiring guard ring 47G may be disposed at substantially the same level as the first lower wiring 47. The lowermost surface of the first lower wiring guard ring 47G may form substantially the same plane as the lowermost surface of the first lower wiring 47. The uppermost surface of the first lower wiring guard ring 47G may be disposed at substantially the same level as the uppermost surface of the first lower wiring 47.

The second lower contact plug 51 may pass through the second lower insulating layer 49 in the first active region AR1 to contact the first lower wiring 47. The second lower contact guard ring 51G may pass through the second lower insulating layer 49 in the first guard ring region GR1 to contact the first lower wiring guard ring 47G. The second lower contact guard ring 51G may include the same material and may be formed simultaneously with the second lower contact plug 51. The second lower contact guard ring 51G may have substantially the same thickness as the second lower contact plug 51. The second lower contact guard ring 51G may be disposed at substantially the same level as the second lower contact plug 51. The upper surface of the second lower contact guard ring 51G, the upper surface of the second lower contact plug 51 and the upper surface of the second lower insulating layer 49 may form substantially the same plane.

In an embodiment, the second lower contact plug 51 may include a corresponding one 51B of the second lower contact barrier layers 51B and 51B′ and a corresponding one 51C of the second lower contact conductive layers 51C and 51C′. The second lower contact guard ring 51G may include the corresponding other one 51B′ of the second lower contact barrier layers 51B and 51B′ and the corresponding other one 51C′ of the second lower contact conductive layers 51C and 51C′. The second lower contact barrier layers 51B and 51B′ may surround the side surfaces of the second lower contact conductive layers 51C and 51C′. The upper surfaces of the second lower insulating layer 49, the second lower contact barrier layers 51B and 51B′ and the second lower contact conductive layers 51C and 51C′ may form substantially the same plane.

The second lower wiring 53 may be disposed on the second lower insulating layer 49 in the first active region AR1. The second lower wiring 53 may contact the second lower contact plug 51. The third lower insulating layer 56 may cover the second lower wiring 53. The second lower wiring guard ring 53G may be disposed on the second lower insulating layer 49 in the first guard ring region GR1. The second lower wiring guard ring 53G may contact the second lower contact guard ring 51G. The third lower insulating layer 56 may cover the second lower wiring guard ring 53G.

The second lower wiring guard ring 53G may include the same material and may be formed simultaneously with the second lower wiring 53. The second lower wiring guard ring 53G may have substantially the same thickness as the second lower wiring 53. The second lower wiring guard ring 53G may be disposed at substantially the same level as the second lower wiring 53. The lowermost surface of the second lower wiring guard ring 53G may form substantially the same plane as the lowermost surface of the second lower wiring 53. The uppermost surface of the second lower wiring guard ring 53G may be disposed at substantially the same level as the uppermost surface of the second lower wiring 53.

In an embodiment, the second lower wiring conductive layers 53C and 53C′ may be disposed on the second lower wiring barrier layers 53B and 53B′. The second lower wiring 53 may include a corresponding one 53B of the second lower wiring barrier layers 53B and 53B′ and a corresponding one 53C of the second lower wiring conductive layers 53C and 53C′. The second lower wiring guard ring 53G may include the corresponding other one 53B′ of the second lower wiring barrier layers 53B and 53B′ and the corresponding other one 53C′ of the second lower wiring conductive layers 53C and 53C′.

The corresponding one 53B of the second lower wiring barrier layers 53B and 53B′ may contact the corresponding one 51B of the second lower contact barrier layers 51B and 51B′ and the corresponding one 51C of the second lower contact conductive layers 51C and 51C′. The corresponding other one 53B′ of the second lower wiring barrier layers 53B and 53B′ may contact the corresponding other one 51B′ of the second lower contact barrier layers 51B and 51B′ and the corresponding other one 51C′ of the second lower contact conductive layers 51C and 51C′.

The upper insulating bonding layer 82, the second upper insulating layer 80, the first upper insulating layer 74 and the third upper insulating layer 112 may be sequentially stacked on the lower insulating bonding layer 58. Each of the upper insulating bonding layer 82, the second upper insulating layer 80, the first upper insulating layer 74 and the third upper insulating layer 112 may extend from the second active region AR2 to the second guard ring region GR2.

The lower insulating bonding layer 58 may cover the third lower insulating layer 56. The upper insulating bonding layer 82 may be bonded onto the lower insulating bonding layer 58. The interface IF may be formed between the lower insulating bonding layer 58 and the upper insulating bonding layer 82. The second upper insulating layer 80 may be disposed on the upper insulating bonding layer 82. The second upper insulating layer 80 may be disposed between the upper insulating bonding layer 82 and the first upper insulating layer 74.

The bit line 77 may be disposed in the second upper insulating layer 80 in the second active region AR2. The second upper insulating layer 80 may be interposed between the lower surface of the bit line 77 and the upper insulating bonding layers 82. The bit guard ring 77G may be disposed in the second upper insulating layer 80 in the second guard ring region GR2. The second upper insulating layer 80 may be interposed between the lower surface of the bit guard ring 77G and the upper insulating bonding layers 82.

The bit guard ring 77G may include the same material and may be formed simultaneously with the bit line 77. The bit guard ring 77G may have substantially the same thickness as the bit line 77. The bit guard ring 77G may be disposed at substantially the same level as the bit line 77. The lowermost surface of the bit guard ring 77G may be disposed at substantially the same level as the lowermost surface of the bit line 77. The uppermost surface of the bit guard ring 77G may be disposed at substantially the same level as the uppermost surface of the bit line 77. In an embodiment, the distance between the lower surface of the bit guard ring 77G and the upper insulating bonding layers 82 may be substantially the same as the distance between the lower surface of the bit line 77 and the upper insulating bonding layers 82. The distance between the lower surface of the bit guard ring 77G and the interface IF may be substantially the same as the distance between the lower surface of the bit line 77 and the interface IF.

In an embodiment, the upper surfaces of the second upper insulating layer 80, the bit line 77 and the bit guard ring 77G may form substantially the same plane. The bit line 77 may include the bit conductive layer 77C and the bit barrier layer 77B on the bit conductive layer 77C. The bit guard ring 77G may include the bit conductive layer 77C′ and the bit barrier layer 77B′ on the bit conductive layer 77C′. The upper surfaces of the second upper insulating layer 80 and the bit barrier layers 77B and 77B′ may form substantially the same plane. The distance between the lower surface of the bit conductive layer 77C′ and the upper insulating bonding layer 82 may be substantially the same as the distance between the lower surface of the bit conductive layer 77C and the upper insulating bonding layer 82. The distance between the lower surface of the bit conductive layer 77C′ and the interface IF may be substantially the same as the distance between the lower surface of the bit conductive layer 77C and the interface IF.

The upper channel 65, the upper gate insulating layer 67, the upper gate electrode 69, the upper source region 71, the first silicide layer 75, the upper drain region 83, the second upper contact plug 86 and the second silicide layer 89 may be disposed in the first upper insulating layer 74 in the second active region AR2.

The first silicide layer 75 may be disposed on the bit line 77. The first silicide layer 75 may contact the bit barrier layer 77B. The upper source region 71 may be disposed on the first silicide layer 75. The upper source region 71 may contact the first silicide layer 75. The upper channel 65 may be disposed on the upper source region 71. The upper channel 65 may contact the upper source region 71. The upper drain region 83 may be disposed on the upper channel 65. The upper drain region 83 may contact the upper channel 65. The second silicide layer 89 may be disposed on the upper drain region 83. The second silicide layer 89 may contact the upper drain region 83. The upper channel 65 may be electrically connected to the bit line 77.

The upper gate insulating layer 67 may be disposed on the side surface of the upper channel 65. The upper gate electrode 69 may be disposed on the side surface of the upper channel 65. The upper gate insulating layer 67 may be interposed between the upper gate electrode 69 and the upper channel 65.

The first upper contact plug 85 may pass through the first upper insulating layer 74, the second upper insulating layer 80, the upper insulating bonding layer 82, the interface IF, the lower insulating bonding layer 58 and the third lower insulating layer 56 to contact the second lower wiring 53. The first upper contact guard ring 85G may pass through the first upper insulating layer 74, the second upper insulating layer 80, the upper insulating bonding layer 82, the interface IF, the lower insulating bonding layer 58 and the third lower insulating layer 56 to contact the second lower wiring guard ring 53G.

In an embodiment, the first upper contact plug 85 may include a corresponding one 85B of the first upper contact barrier layers 85B and 85B′ and a corresponding one 85C of the first upper contact conductive layers 85C and 85C′. The first upper contact guard ring 85G may include the corresponding other one 85B′ of the first upper contact barrier layers 85B and 85B′ and the corresponding other one 85C′ of the first upper contact conductive layers 85C and 85C′. The first upper contact barrier layers 85B and 85B′ may surround the side surfaces and the lower surfaces of the first upper contact conductive layers 85C and 85C′. The corresponding one 85B of the first upper contact barrier layers 85B and 85B′ may contact the upper surface of the corresponding one 53C of the second lower wiring conductive layers 53C and 53C′. The corresponding other one 85B′ of the first upper contact barrier layers 85B and 85B′ may contact the upper surface of the corresponding other one 53C′ of the second lower wiring conductive layers 53C and 53C′.

The first upper contact guard ring 85G may have substantially the same thickness as the first upper contact plug 85. The first upper contact guard ring 85G may be disposed at substantially the same level as the first upper contact plug 85. The lowermost surface of the first upper contact guard ring 85G may be disposed at substantially the same level as the lowermost surface of the first upper contact plug 85. The lowermost surface of the corresponding other one 85B′ of the first upper contact barrier layers 85B and 85B′ may be disposed at substantially the same level as the lowermost surface of the corresponding one 85B of the first upper contact barrier layers 85B and 85B′.

The second upper contact plug 86 may pass through the first upper insulating layer 74 and contact the bit line 77. The second upper contact plug 86 may be spaced apart from the first upper contact plug 85. The second upper contact plug 86 may contact the bit barrier layer 77B. The second upper contact guard ring 86G may be disposed in the first upper insulating layer 74 in the second guard ring region GR2. The second upper contact guard ring 86G may be spaced apart from the first upper contact guard ring 85G. The second upper contact guard ring 86G may pass through the first upper insulating layer 74 in the second guard ring region GR2 and contact the bit guard ring 77G. The second upper contact guard ring 86G may contact the bit barrier layer 77B′.

In an embodiment, the second upper contact plug 86 may include a corresponding one 86B of the second upper contact barrier layers 86B and 86B′ and a corresponding one 86C of the second upper contact conductive layers 86C and 86C′. The corresponding one 86B of the second upper contact barrier layers 86B and 86B′ may surround the side surface and the lower surface of the corresponding one 86C of the second upper contact conductive layers 86C and 86C′. The second upper contact guard ring 86G may include the corresponding other one 86B′ of the second upper contact barrier layers 86B and 86B′ and the corresponding other one 86C′ of the second upper contact conductive layers 86C and 86C′. The corresponding other one 86B′ of the second upper contact barrier layers 86B and 86B′ may surround the side surface and the lower surface of the corresponding other one 86C′ of the second upper contact conductive layers 86C and 86C′. The corresponding one 86B of the second upper contact barrier layers 86B and 86B′ may contact the bit barrier layer 77B. The corresponding other one 86B′ of the second upper contact barrier layers 86B and 86B′ may contact the bit barrier layer 77B′.

The second upper contact guard ring 86G may have substantially the same thickness as the second upper contact plug 86. The second upper contact guard ring 86G may be disposed at substantially the same level as the second upper contact plug 86. The lowermost surface of the second upper contact guard ring 86G may be disposed at substantially the same level as the lowermost surface of the second upper contact plug 86. The lowermost surface of the corresponding other one 86B′ of the second upper contact barrier layers 86B and 86B′ may be disposed at substantially the same level as the lowermost surface of the corresponding one 86B of the second upper contact barrier layers 86B and 86B′. The upper surfaces of the first upper insulating layer 74, the second silicide layer 89, the first upper contact barrier layers 85B and 85B′, the first upper contact conductive layers 85C and 85C′, the second upper contact barrier layers 86B and 86B′ and the second upper contact conductive layers 86C and 86C′ may form substantially the same plane. In an embodiment, the first upper contact plug 85, the second upper contact plug 86, the first upper contact guard ring 85G and the second upper contact guard ring 86G may include the same material and may be formed simultaneously.

The landing pad 91 and the first upper wiring 91W may be disposed on the first upper insulating layer 74 in the second active region AR2. The landing pad 91 may be disposed on the upper drain region 83. The second silicide layer 89 may be interposed between the upper drain region 83 and the landing pad 91. The landing pad 91 may contact the second silicide layer 89. The landing pad 91 may be electrically connected to the upper channel 65.

The first upper wiring 91W may be disposed on the first upper contact plug 85 and the second upper contact plug 86. The first upper wiring 91W may contact the first upper contact plug 85 and the second upper contact plug 86. The first upper wiring guard ring 91G may be disposed on the first upper insulating layer 74 in the second guard ring region GR2. The first upper wiring guard ring 91G may be disposed on the first upper contact guard ring 85G and the second upper contact guard ring 86G. The first upper wiring guard ring 91G may contact the first upper contact guard ring 85G and the second upper contact guard ring 86G.

The landing pad 91, the first upper wiring 91W and the first upper wiring guard ring 91G may have substantially the same thickness. The landing pad 91, the first upper wiring 91W and the first upper wiring guard ring 91G may include the same material and may be formed simultaneously. The landing pad 91, the first upper wiring 91W and the first upper wiring guard ring 91G may be disposed at substantially the same level. The lower surfaces of the landing pad 91, the first upper wiring 91W and the first upper wiring guard ring 91G may be disposed at substantially the same level. The upper surfaces of the landing pad 91, the first upper wiring 91W and the first upper wiring guard ring 91G may be disposed at substantially the same level.

In an embodiment, the landing pad conductive layers 91C, 91C′ and 91C″ may be disposed on the landing pad barrier layers 91B, 91B′ and 91B″. The landing pad 91 may include a corresponding one 91B of the landing pad barrier layers 91B, 91B′ and 91B″ and a corresponding one 91C of the landing pad conductive layers 91C, 91C′ and 91C″. The corresponding one 91B of the landing pad barrier layers 91B, 91B′ and 91B″ may contact the second silicide layer 89. The first upper wiring guard ring 91G may include a corresponding other one 91B′ of the landing pad barrier layers 91B, 91B′ and 91B″ and a corresponding other one 91C′ of the landing pad conductive layers 91C, 91C′ and 91C″. The corresponding other one 91B′ of the landing pad barrier layers 91B, 91B′ and 91B″ may contact the corresponding other one 85B′ of the first upper contact barrier layers 85B and 85B′, the corresponding other one 85C′ of the first upper contact conductive layers 85C and 85C′, the corresponding other one 86B′ of the second upper contact barrier layers 86B and 86B′ and the corresponding other one 86C′ of the second upper contact conductive layers 86C and 86C′.

The first upper wiring 91W may include the corresponding other one 91B″ of the landing pad barrier layers 91B, 91B′ and 91B″ and the corresponding other one 91C″ of the landing pad conductive layers 91C, 91C′ and 91C″. The corresponding other one 91B″ of the landing pad barrier layers 91B, 91B′ and 91B″ may contact the corresponding one 85B of the first upper contact barrier layers 85B and 85B′, the corresponding one 85C of the first upper contact conductive layers 85C and 85C′, the corresponding one 86B of the second upper contact barrier layers 86B and 86B′ and the corresponding one 86C of the second upper contact conductive layers 86C and 86C′.

The etch stop layer 95 may cover the first upper insulating layer 74, the landing pad 91, the first upper wiring 91W and the first upper wiring guard ring 91G. The etch stop layer 95 may extend from the second active region AR2 to the second guard ring region GR2. The lower electrode 103, the support 104, the capacitor dielectric layer 106 and the upper electrode 107 may be disposed in the second active region AR2.

The lower electrode 103 may be disposed on the landing pad 91. The lower electrode 103 may pass through the etch stop layer 95 and contact the landing pad 91. The lower electrode 103 may have a height greater than a horizontal width. The support 104 may be disposed on the side surface of the lower electrode 103. The support 104 may be spaced apart from the etch stop layer 95. The support 104 may be disposed around the upper region of the lower electrode 103. The support 104 may contact the side surface of the lower electrode 103.

The capacitor dielectric layer 106 may be disposed on the lower electrode 103. The upper electrode 107 may be disposed on the lower electrode 103. The capacitor dielectric layer 106 may be interposed between the lower electrode 103 and the upper electrode 107. The upper electrode 107 may extend on the support 104 and the etch stop layer 95. The capacitor dielectric layer 106 may extend between the etch stop layer 95 and the upper electrode 107 and between the support 104 and the upper electrode 107.

The lower electrode 103, the capacitor dielectric layer 106 and the upper electrode 107 may constitute a capacitor. The upper channel 65, the upper gate insulating layer 67, the upper gate electrode 69, the upper source region 71 and the upper drain region 83 may constitute an upper transistor.

In an embodiment, the lower electrode 103, the capacitor dielectric layer 106 and the upper electrode 107 may correspond to a cell capacitor. The lower electrode 103 and the landing pad 91 may correspond to a storage node. The upper transistor may correspond to a cell transistor. The cell transistor and the cell capacitor may constitute the memory cell of DRAM.

In an embodiment, the upper transistor may correspond to a switching element. The switching element may include a planar transistor, a recess channel transistor, a vertical transistor, a fin field effect transistor (finFET), a gate all around (GAA) transistor, a multi-bridge channel transistor, or a combination thereof. The capacitor may correspond to a data storage element. The data storage element may include each of various structures such as volatile memory, nonvolatile memory or a combination thereof.

The third upper insulating layer 112 may cover the etch stop layer 95, the lower electrode 103, the support 104, the capacitor dielectric layer 106 and the upper electrode 107. The third upper insulating layer 112 may extend from the second active region AR2 to the second guard ring region GR2. The third upper contact plug 115 may be disposed in the second active region AR2. A selected one of third upper contact plugs 115 may pass through the third upper insulating layer 112 and contact the upper electrode 107. Some of the third upper contact plugs 115 may pass through the third upper insulating layer 112 and the etch stop layer 95 and contact the first upper wirings 91W. The third upper contact guard ring 115G may be disposed in the second guard ring region GR2. The third upper contact guard ring 115G may pass through the third upper insulating layer 112 and the etch stop layer 95 and contact the first upper wiring guard ring 91G.

The third upper contact guard ring 115G may include the same material and may be formed simultaneously with the third upper contact plug 115. The third upper contact plug 115 may include a selected one 115B of the third upper contact barrier layers 115B and 115B′ and a selected one 115C of the third upper contact conductive layers 115C and 115C′. The third upper contact guard ring 115G may include the selected other one 115B′ of the third upper contact barrier layers 115B and 115B′ and the selected other one 115C′ of the third upper contact conductive layers 115C and 115C′. The third upper contact barrier layers 115B and 115B′ may surround the side surfaces and the lower surfaces of the third upper contact conductive layers 115C and 115C′. The selected one 115B of the third upper contact barrier layers 115B and 115B′ may contact the corresponding other one 91C″ of the landing pad conductive layers 91C, 91C′ and 91C″. The selected other one 115B′ of the third upper contact barrier layers 115B and 115B′ may contact the corresponding other one 91C′ of the landing pad conductive layers 91C, 91C′ and 91C″.

The second upper wiring 117 may be disposed on the third upper insulating layer 112 in the second active region AR2. The second upper wiring 117 may contact the third upper contact plug 115. The second upper wiring guard ring 117G may be disposed on the third upper insulating layer 112 in the second guard ring region GR2. The second upper wiring guard ring 117G may contact the third upper contact guard ring 115G. The second upper wiring guard ring 117G may be disposed at substantially the same level as the second upper wiring 117. The second upper wiring guard ring 117G may have substantially the same thickness as the second upper wiring 117. The second upper wiring guard ring 117G may include the same material and may be formed simultaneously with the second upper wiring 117.

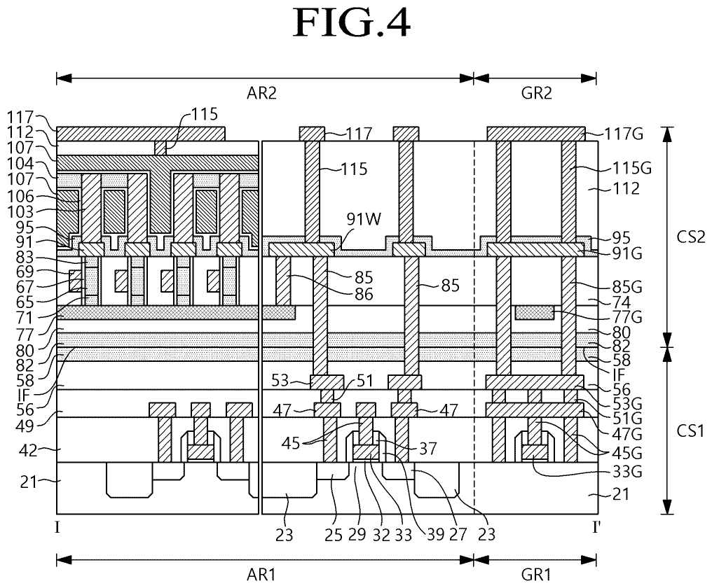

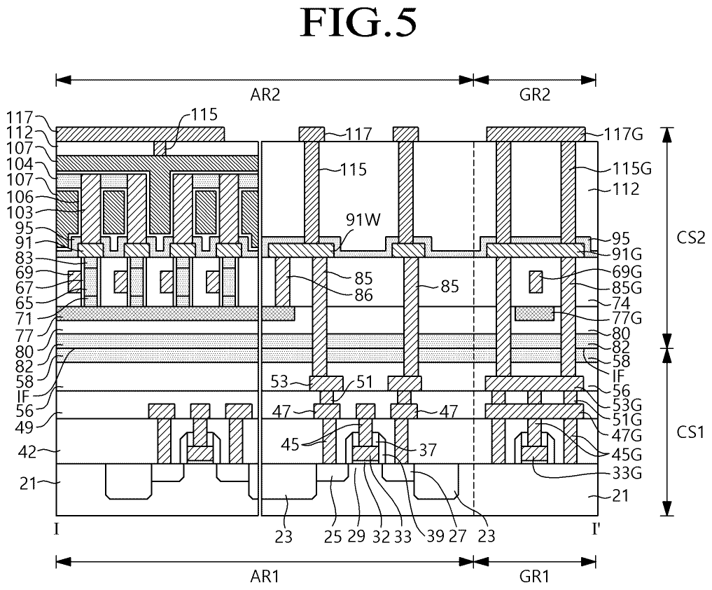

FIG. 4 and FIG. 5 are cross-sectional views of semiconductor devices according to embodiments of the present disclosure. In an embodiment, FIG. 4 and FIG. 5 may be cross-sectional views taken along the section line I-I′ of FIG. 3.

Referring to FIG. 4, a semiconductor device according to embodiments of the present disclosure may include a first substrate 21, an isolation layer 23, a lower source region 25, a lower drain region 27, a lower channel region 29, a lower gate insulating layer 32, a lower gate electrode 33, a lower gate guard ring 33G, a gate capping layer 37, a gate spacer 39, a first lower insulating layer 42, a first lower contact plug 45, a first lower contact guard ring 45G, a first lower wiring 47, a first lower wiring guard ring 47G, a second lower insulating layer 49, a second lower contact plug 51, a second lower contact guard ring 51G, a second lower wiring 53, a second lower wiring guard ring 53G, a third lower insulating layer 56, a lower insulating bonding layer 58, an upper channel 65, an upper gate insulating layer 67, an upper gate electrode 69, an upper source region 71, a first upper insulating layer 74, a bit line 77, a bit guard ring 77G, a second upper insulating layer 80, an upper insulating bonding layer 82, an interface IF, an upper drain region 83, a first upper contact plug 85, a first upper contact guard ring 85G, a second upper contact plug 86, a landing pad 91, a first upper wiring 91W, a first upper wiring guard ring 91G, an etch stop layer 95, a lower electrode 103, a support 104, a capacitor dielectric layer 106, an upper electrode 107, a third upper insulating layer 112, a third upper contact plug 115, a third upper contact guard ring 115G, a second upper wiring 117, and a second upper wiring guard ring 117G. In an embodiment, a second upper contact guard ring (86G of FIG. 1) may be omitted.

Referring to FIG. 5, a semiconductor device according to embodiments of the present disclosure may include a first substrate 21, an isolation layer 23, a lower source region 25, a lower drain region 27, a lower channel region 29, a lower gate insulating layer 32, a lower gate electrode 33, a lower gate guard ring 33G, a gate capping layer 37, a gate spacer 39, a first lower insulating layer 42, a first lower contact plug 45, a first lower contact guard ring 45G, a first lower wiring 47, a first lower wiring guard ring 47G, a second lower insulating layer 49, a second lower contact plug 51, a second lower contact guard ring 51G, a second lower wiring 53, a second lower wiring guard ring 53G, a third lower insulating layer 56, a lower insulating bonding layer 58, an upper channel 65, an upper gate insulating layer 67, an upper gate electrode 69, an upper gate guard ring 69G, an upper source region 71, a first upper insulating layer 74, a bit line 77, a bit guard ring 77G, a second upper insulating layer 80, an upper insulating bonding layer 82, an interface IF, an upper drain region 83, a first upper contact plug 85, a first upper contact guard ring 85G, a second upper contact plug 86, a landing pad 91, a first upper wiring 91W, a first upper wiring guard ring 91G, an etch stop layer 95, a lower electrode 103, a support 104, a capacitor dielectric layer 106, an upper electrode 107, a third upper insulating layer 112, a third upper contact plug 115, a third upper contact guard ring 115G, a second upper wiring 117, and a second upper wiring guard ring 117G.

In an embodiment, a second upper contact guard ring (86G of FIG. 1) may be omitted. The upper gate guard ring 69G may be disposed in the first upper insulating layer 74 in the second guard ring region GR2. The upper gate guard ring 69G may include the same material and may be formed simultaneously with the upper gate electrode 69. The upper gate guard ring 69G may have substantially the same thickness as the upper gate electrode 69. The upper gate guard ring 69G may be disposed at substantially the same level as the upper gate electrode 69. The lowermost surface of the upper gate guard ring 69G may be disposed at substantially the same level as the lowermost surface of the upper gate electrode 69. The uppermost surface of the upper gate guard ring 69G may be disposed at substantially the same level as the uppermost surface of the upper gate electrode 69.

The upper gate guard ring 69G may be spaced apart from the first upper contact guard ring 85G. The uppermost surface of the upper gate guard ring 69G may be disposed at a level lower than the uppermost surface of the first upper contact guard ring 85G. The lowermost surface of the upper gate guard ring 69G may be disposed at a level higher than the lowermost surface of the first upper contact guard ring 85G. The upper gate guard ring 69G may be spaced apart from the bit guard ring 77G.

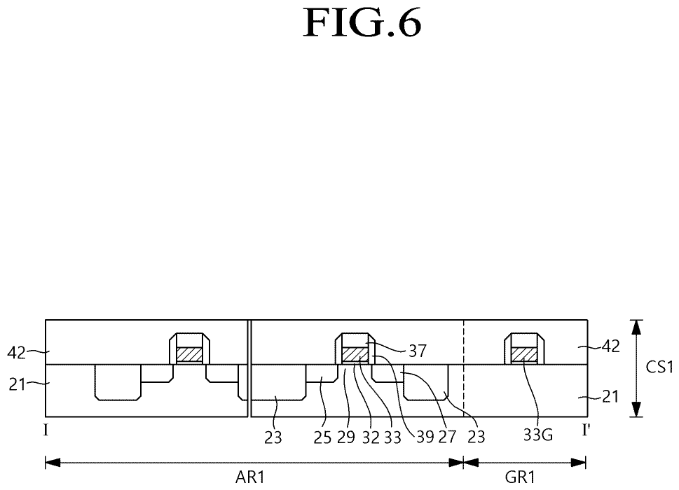

FIG. 6 to FIG. 21 are cross-sectional views for describing a method of forming a semiconductor device according to embodiments of the present disclosure. In an embodiment, FIG. 6 to FIG. 21 may be cross-sectional views taken along the section line I-I′ of FIG. 3.

Referring to FIG. 6, an isolation layer 23, a lower source region 25, a lower drain region 27, a lower channel region 29, a lower gate insulating layer 32, a lower gate electrode 33, a lower gate guard ring 33G, a gate capping layer 37, a gate spacer 39 and a first lower insulating layer 42 may be formed on a first substrate 21.

The first substrate 21 may extend from a first active region AR1 to a first guard ring region GR1. As illustrated in FIG. 3, the first guard ring region GR1 may surround the edge of the first active region AR1. The first substrate 21 may include a semiconductor substrate such as a silicon wafer or a silicon-on-insulator (SOI) wafer. The first substrate 21 may include a III-V group semiconductor substrate, for example, a compound semiconductor substrate such as gallium arsenide (GaAs). The first substrate 21 may include monocrystalline silicon, polysilicon, amorphous silicon, monocrystalline silicon germanium, polycrystalline silicon germanium, carbon-doped silicon or a combination thereof.

The isolation layer 23 may be formed from the upper surface of the first substrate 21 to a predetermined depth using a trench isolation technique. The lower source region 25 and the lower drain region 27 may be formed from the upper surface of the first substrate 21 to a predetermined depth using an ion implantation technique. The lower channel region 29 may be delimited between the lower source region 25 and the lower drain region 27 in the first substrate 21. The lower source region 25 and the lower drain region 27 may include impurities of a conductivity type different from the lower channel region 29.

In an embodiment, the lower channel region 29 may include a semiconductor layer such as monocrystalline silicon with P-type impurities. The lower source region 25 and the lower drain region 27 may include a semiconductor layer with N-type impurities. In an embodiment, the lower channel region 29 may include a semiconductor layer with N-type impurities, and the lower source region 25 and the lower drain region 27 may include a semiconductor layer with P-type impurities.

The lower gate insulating layer 32 may be formed on the lower channel region 29. The lower gate insulating layer 32 may include at least two selected from the group consisting of silicon (Si), oxygen (O), nitrogen (N), carbon (C), boron (B), phosphorus (P) and hydrogen (H). The lower gate insulating layer 32 may include, for example, silicon oxide, silicon nitride, silicon oxynitride, high-k dielectric or a combination thereof.

The lower gate electrode 33 may be formed on the lower gate insulating layer 32. The lower gate electrode 33 may be aligned on the lower channel region 29. The gate capping layer 37 may be formed on the lower gate electrode 33. The gate capping layer 37 may cover the lower gate electrode 33. The gate spacer 39 may be formed on the side surfaces of the gate capping layer 37 and the lower gate electrode 33.

The lower gate guard ring 33G may be formed on the first substrate 21 in the first guard ring region GR1 while forming the lower gate electrode 33. The lower gate guard ring 33G may include the same material and may be formed simultaneously with the lower gate electrode 33. The lower gate guard ring 33G and the lower gate electrode 33 may include metal, metal nitride, metal oxide, metal silicide, polysilicon, conductive carbon or a combination thereof. The first lower insulating layer 42 may cover the lower gate insulating layer 32, the lower gate electrode 33, the gate capping layer 37, the gate spacer 39 and the lower gate guard ring 33G. In an embodiment, components similar to the lower gate insulating layer 32, the gate capping layer 37 and the gate spacer 39 may be selectively formed around the lower gate guard ring 33G, but are not described for the sake of simplicity in description.

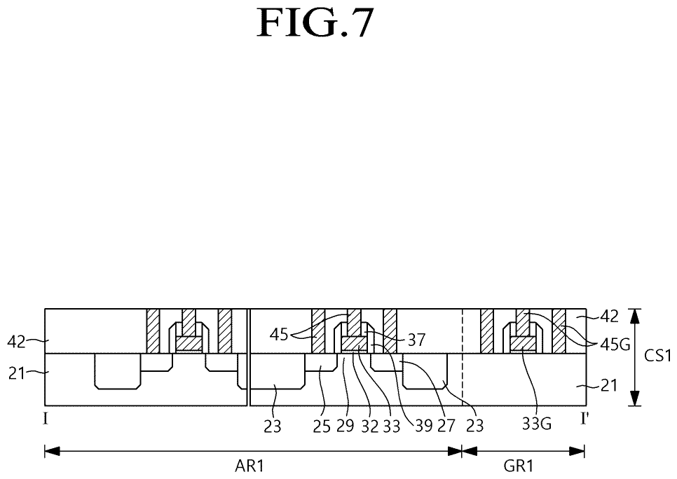

Referring to FIG. 7, a first lower contact plug 45 and a first lower contact guard ring 45G may be formed in the first lower insulating layer 42. The first lower contact plug 45 may pass through the first lower insulating layer 42 to contact the lower source region 25, the lower drain region 27 or the lower gate electrode 33. The first lower contact guard ring 45G may pass through the first lower insulating layer 42 to contact the lower gate guard ring 33G or the first substrate 21. The first lower contact guard ring 45G may include the same material and may be formed simultaneously with the first lower contact plug 45.

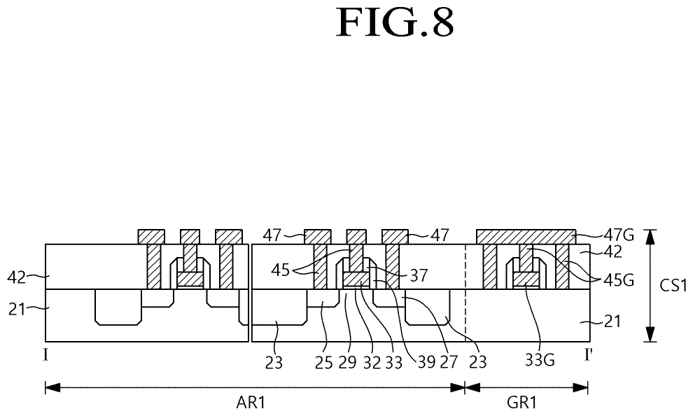

Referring to FIG. 8, a first lower wiring 47 and a first lower wiring guard ring 47G may be formed on the first lower insulating layer 42. The first lower wiring 47 may contact the first lower contact plug 45. The first lower wiring guard ring 47G may contact the first lower contact guard ring 45G. The first lower wiring guard ring 47G may include the same material and may be formed simultaneously with the first lower wiring 47.

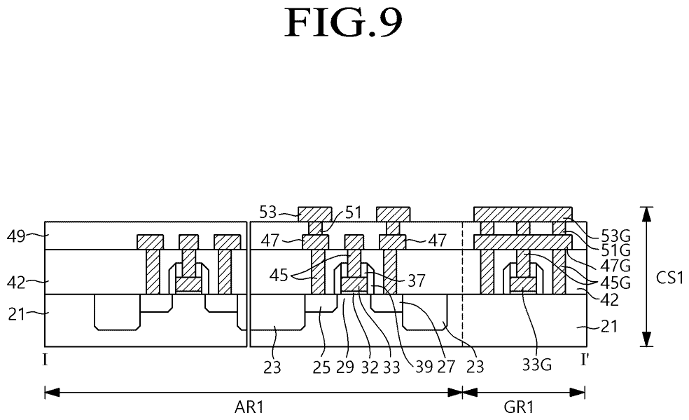

Referring to FIG. 9, a second lower insulating layer 49 may be formed on the first lower insulating layer 42. The second lower insulating layer 49 may cover the first lower wiring 47 and the first lower wiring guard ring 47G.

A second lower contact plug 51 and a second lower contact guard ring 51G may be formed in the second lower insulating layer 49. The second lower contact plug 51 may pass through the second lower insulating layer 49 to contact the first lower wiring 47. The second lower contact guard ring 51G may pass through the second lower insulating layer 49 to contact the first lower wiring guard ring 47G. The second lower contact guard ring 51G may include the same material and may be formed simultaneously with the second lower contact plug 51.

A second lower wiring 53 and a second lower wiring guard ring 53G may be formed on the second lower insulating layer 49 in the first active region AR1 and the first guard ring region GR1, respectively. The second lower wiring 53 may contact the second lower contact plug 51. The second lower wiring guard ring 53G may contact the second lower contact guard ring 51G. The second lower wiring guard ring 53G may include the same material and may be formed simultaneously with the second lower wiring 53.

As illustrated in FIG. 2, the second lower contact plug 51 may include a corresponding one 51B of second lower contact barrier layers 51B and 51B′ and a corresponding one 51C of second lower contact conductive layers 51C and 51C′. The second lower contact guard ring 51G may include the corresponding other one 51B′ of the second lower contact barrier layers 51B and 51B′ and the corresponding other one 51C′ of the second lower contact conductive layers 51C and 51C′. The second lower wiring 53 may include a corresponding one 53B of second lower wiring barrier layers 53B and 53B′ and a corresponding one 53C of second lower wiring conductive layers 53C and 53C′. The second lower wiring guard ring 53G may include the corresponding other one 53B′ of the second lower wiring barrier layers 53B and 53B′ and the corresponding other one 53C′ of the second lower wiring conductive layers 53C and 53C′.

The second lower contact barrier layers 51B and 51B′ and the second lower wiring barrier layers 53B and 53B′ may include titanium (Ti), titanium nitride (TiN), tantalum (Ta), tantalum nitride (TaN) or a combination thereof. The second lower contact conductive layers 51C and 51C′ and the second lower wiring conductive layers 53C and 53C′ may include metal, metal nitride, metal oxide, metal silicide, polysilicon, conductive carbon or a combination thereof. In an embodiment, the second lower contact conductive layers 51C and 51C′ and the second lower wiring conductive layers 53C and 53C′ may include tungsten (W). In an embodiment, the first lower contact plug 45, the first lower contact guard ring 45G, the first lower wiring 47 and the first lower wiring guard ring 47G may include materials similar to the second lower contact plug 51, the second lower contact guard ring 51G, the second lower wiring 53 and the second lower wiring guard ring 53G.

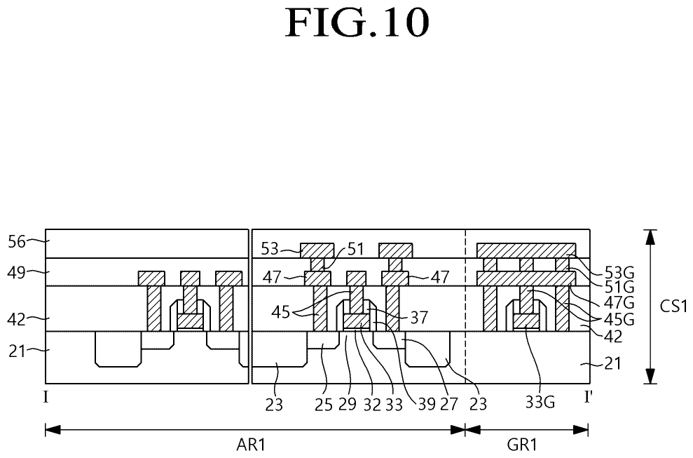

Referring to FIG. 10, a third lower insulating layer 56 may be formed on the second lower insulating layer 49 to cover the second lower wiring 53 and the second lower wiring guard ring 53G. Forming the third lower insulating layer 56 may include a thin film formation process and a planarization process. The thin film formation process may involve depositing a thin layer of material using a technique such as, for example, one of a Chemical Vapor Deposition (CVD) or Physical Vapor Deposition (PVD). In an embodiment, the upper surface of the third lower insulating layer 56 may be planarized using a chemical mechanical polishing (CMP) process. In the first active region AR1 and the first guard ring region GR1, the upper surface of the third lower insulating layer 56 may have a flat surface.

The isolation layer 23, the gate capping layer 37, the gate spacer 39, the first lower insulating layer 42, the second lower insulating layer 49 and the third lower insulating layer 56 may include at least two selected from the group consisting of silicon (Si), oxygen (O), nitrogen (N), carbon (C), boron (B), phosphorus (P) and hydrogen (H). The isolation layer 23, the gate capping layer 37, the gate spacer 39, the first lower insulating layer 42, the second lower insulating layer 49 and the third lower insulating layer 56 may include silicon oxide, silicon nitride, silicon oxynitride, low-k dielectric, high-k dielectric or a combination thereof. In an embodiment, the third lower insulating layer 56 may include SiOH(silicon hydroxide), SiCH(silicon carbide hydrate), SiCOH(silicon carbon oxide hydrate) or a combination thereof.

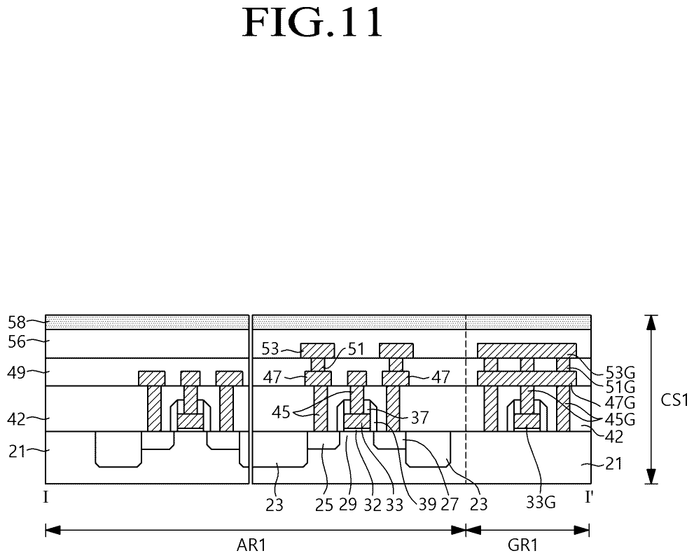

Referring to FIG. 11, a lower insulating bonding layer 58 may be formed on the third lower insulating layer 56. Forming the lower insulating bonding layer 58 may include a thin film formation process and a planarization process. In an embodiment, the upper surface of the lower insulating bonding layer 58 may be planarized using a chemical mechanical polishing (CMP) process. In the first active region AR1 and the first guard ring region GR1, the upper surface of the lower insulating bonding layer 58 may have a flat surface. The lower insulating bonding layer 58 may include at least two selected from the group consisting of silicon (Si), oxygen (O), nitrogen (N), carbon (C), boron (B), phosphorus (P) and hydrogen (H). In an embodiment, the lower insulating bonding layer 58 may include SiCN(silicon carbide nitride), SiOCN(silicon oxycarbon nitride), SiOHN(silicon hydroxynitride), SiCHN(silicon-carbon-hydrogen-nitrogen compound), SiOCHN(silicon-oxy-carbon-hydrogen-nitrogen compound) or a combination thereof.

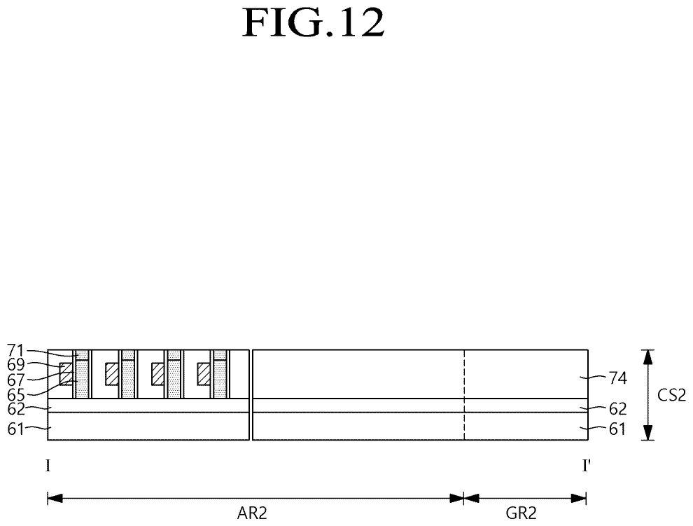

Referring to FIG. 12, a sacrificial insulating layer 62, an upper channel 65, an upper gate insulating layer 67, an upper gate electrode 69, an upper source region 71 and a first upper insulating layer 74 may be formed on a second substrate 61. The second substrate 61 may extend from a second active region AR2 to a second guard ring region GR2. The second substrate 61 may include a material similar to the first substrate 21. The sacrificial insulating layer 62 may cover the second substrate 61. The sacrificial insulating layer 62 may include silicon oxide.

The upper channel 65 may be formed on the sacrificial insulating layer 62. The upper channel 65 may include a semiconductor material such as monocrystalline silicon, polysilicon or a combination thereof. The upper source region 71 may be formed on the upper channel 65. The upper source region 71 may include a semiconductor layer that includes impurities of a conductivity type different from the upper channel 65. In an embodiment, the upper source region 71 may include N-type impurities, and the upper channel 65 may include P-type impurities.

The upper gate insulating layer 67 may be formed on the side surface of the upper channel 65. In an embodiment, the upper gate insulating layer 67 may cover the side surface of the upper channel 65 and extend onto the side surface of the upper source region 71. The upper gate insulating layer 67 may include at least two selected from the group consisting of silicon (Si), oxygen (O), nitrogen (N), carbon (C), boron (B), phosphorus (P) and hydrogen (H). The upper gate insulating layer 67 may include silicon oxide, silicon nitride, silicon oxynitride, high-k dielectric or a combination thereof.

The upper gate electrode 69 may be formed on the side surface of the upper channel 65. The upper gate insulating layer 67 may be interposed between the upper gate electrode 69 and the upper channel 65. The upper gate electrode 69 may include metal, metal nitride, metal oxide, metal silicide, polysilicon, conductive carbon or a combination thereof.

The first upper insulating layer 74 may cover the sacrificial insulating layer 62, the upper channel 65, the upper gate insulating layer 67, the upper gate electrode 69 and the upper source region 71. In an embodiment, the upper surfaces of the first upper insulating layer 74, the upper gate insulating layer 67 and the upper source region 71 may form substantially the same plane.

In an embodiment, as illustrated in FIG. 2, a first silicide layer 75 may be formed on the upper source region 71. In an embodiment, the upper surfaces of the first upper insulating layer 74, the upper gate insulating layer 67 and the first silicide layer 75 may form substantially the same plane. The first silicide layer 75 may include CoSi (cobalt silicide), TiSi (titanium silicide), TaSi (tantalum silicide), NiSi (nickel silicide), WSi (tungsten silicide), or a combination thereof.

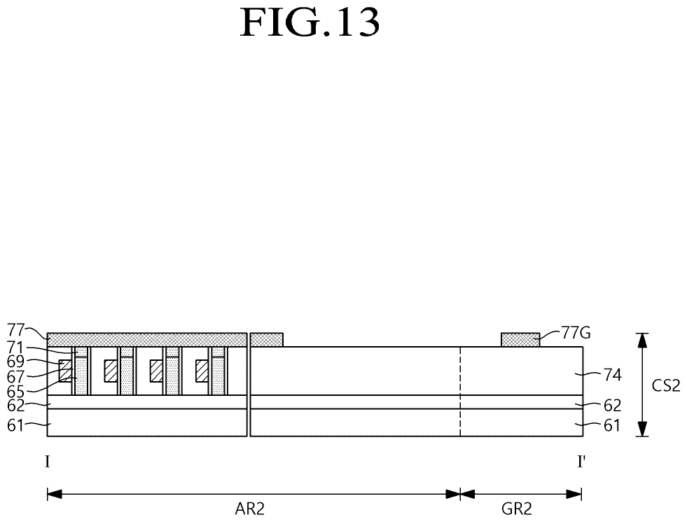

Referring to FIG. 13, a bit line 77 and a bit guard ring 77G may be formed on the first upper insulating layer 74. The bit line 77 may contact the first silicide layer 75. The bit line 77 may be connected to the upper source region 71. The bit guard ring 77G may be formed at substantially the same level as the bit line 77. The bit guard ring 77G may include the same material and may be formed simultaneously with the bit line 77.

In an embodiment, as illustrated in FIG. 2, the bit line 77 and the bit guard ring 77G may include bit barrier layers 77B and 77B′ and bit conductive layers 77C and 77C′. The lower surface of the bit barrier layer 77B may contact the upper surfaces of the first upper insulating layer 74 and the first silicide layer 75. The lower surface of the bit barrier layer 77B′ may contact the upper surface of the first upper insulating layer 74. The bit conductive layers 77C and 77C′ may cover the bit barrier layers 77B and 77B′.

The bit barrier layers 77B and 77B′ may include titanium (Ti), titanium nitride (TiN), tantalum (Ta), tantalum nitride (TaN) or a combination thereof. The bit conductive layers 77C and 77C′ may include metal, metal nitride, metal oxide, metal silicide, polysilicon, conductive carbon or a combination thereof. In an embodiment, the bit conductive layers 77C and 77C′ may include tungsten (W), tungsten nitride (WN) or a combination thereof.

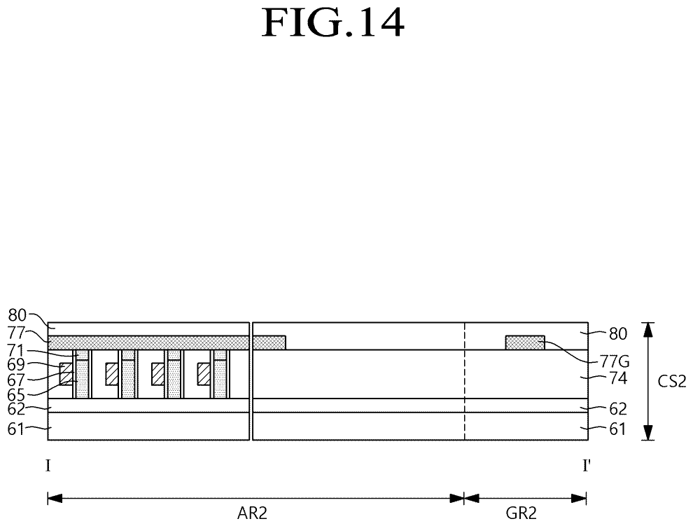

Referring to FIG. 14, a second upper insulating layer 80 may be formed on the first upper insulating layer 74. The second upper insulating layer 80 may cover the bit line 77 and the bit guard ring 77G. Forming the second upper insulating layer 80 may include a thin film formation process and a planarization process. In an embodiment, the upper surface of the second upper insulating layer 80 may be planarized using a chemical mechanical polishing (CMP) process. While the planarization process is performed, the bit guard ring 77G may serve to prevent the second upper insulating layer 80 in the second guard ring region GR2 from being excessively removed. The bit guard ring 77G may serve to prevent unevenness from occurring on the upper surface of the second upper insulating layer 80. In the second active region AR2 and the second guard ring region GR2, the upper surface of the second upper insulating layer 80 may have a flat surface.

The first upper insulating layer 74 and the second upper insulating layer 80 may include at least two selected from the group consisting of silicon (Si), oxygen (O), nitrogen (N), carbon (C), boron (B), phosphorus (P) and hydrogen (H). The first upper insulating layer 74 and the second upper insulating layer 80 may include silicon oxide, silicon nitride, silicon oxynitride, low-k dielectric, high-k dielectric or a combination thereof. In an embodiment, the second upper insulating layer 80 may include SiOH(silicon hydroxide), SiCH(silicon carbide hydrate), SiCOH(silicon carbon oxide hydrate) or a combination thereof.

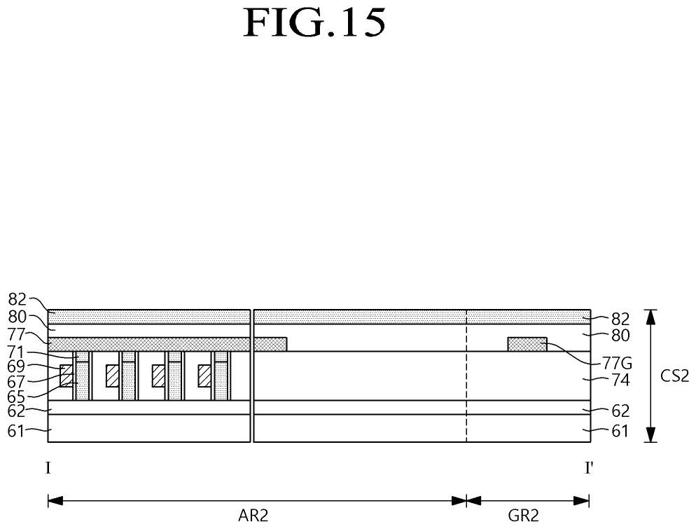

Referring to FIG. 15, an upper insulating bonding layer 82 may be formed on the second upper insulating layer 80. Forming the upper insulating bonding layer 82 may include a thin film formation process and a planarization process. In an embodiment, the upper surface of the upper insulating bonding layer 82 may be planarized using a chemical mechanical polishing (CMP) process. While the planarization process is performed, the bit guard ring 77G may serve to prevent the upper insulating bonding layer 82 in the second guard ring region GR2 from being excessively removed. The bit guard ring 77G may serve to prevent unevenness from occurring on the upper surface of the upper insulating bonding layer 82. In the second active region AR2 and the second guard ring region GR2, the upper surface of the upper insulating bonding layer 82 may have a flat surface.

The upper insulating bonding layer 82 may include at least two selected from the group consisting of silicon (Si), oxygen (O), nitrogen (N), carbon (C), boron (B), phosphorus (P) and hydrogen (H). The upper insulating bonding layer 82 may include SiCN(silicon carbide nitride), SiOCN(silicon oxyncarbon nitride), SiOHN(silicon hydroxynitride), SiCHN(silicon-carbon-hydrogen-nitrogen compound), SiOCHN(silicon-oxy-carbon-hydrogen-nitrogen compound) or a combination thereof. In an embodiment, the upper insulating bonding layer 82 may include the same material as the lower insulating bonding layer 58 (see FIG. 11). The upper insulating bonding layer 82 and the lower insulating bonding layer 58 (see FIG. 11) may include SiCN(silicon carbide nitride).

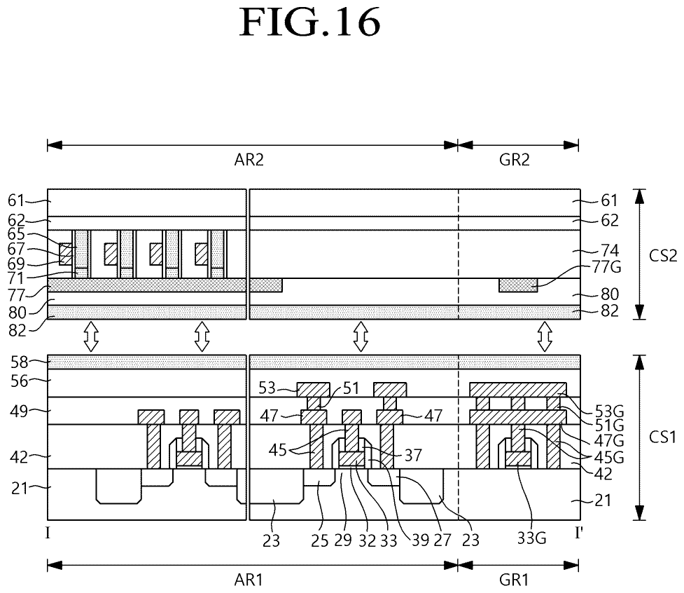

Referring to FIG. 16, a second circuit structure CS2 may be bonded onto a first circuit structure CS1. More specifically, the upper insulating bonding layer 82 may be bonded onto the lower insulating bonding layer 58.

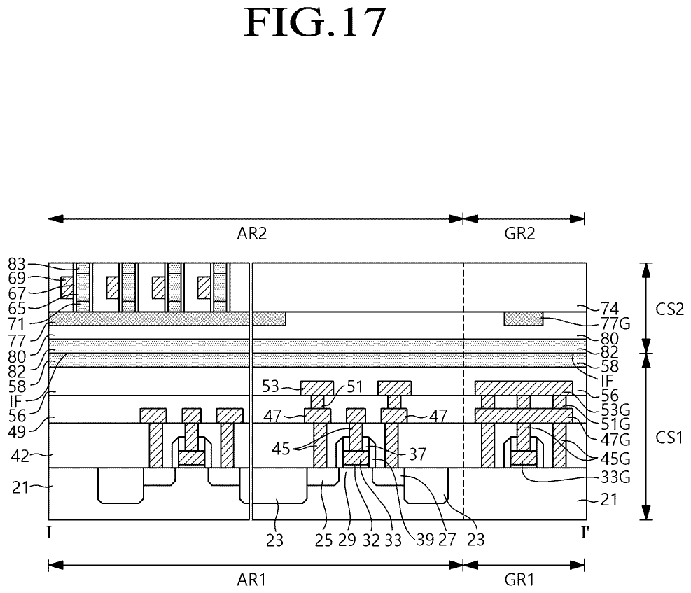

Referring to FIG. 17, the bonding surfaces of the lower insulating bonding layer 58 and the upper insulating bonding layer 82 may have flat surfaces. The upper insulating bonding layer 82 may be densely bonded onto the lower insulating bonding layer 58. An interface IF may be formed between the lower insulating bonding layer 58 and the upper insulating bonding layer 82.

The second substrate 61 and the sacrificial insulating layer 62 may be removed to expose the first upper insulating layer 74. An upper drain region 83 may be formed on the upper channel 65. The upper channel 65 may be delimited between the upper source region 71 and the upper drain region 83. The upper drain region 83 may include a semiconductor layer that includes impurities of a conductivity type different from the upper channel 65. In an embodiment, the upper drain region 83 may include N-type impurities, and the upper channel 65 may include P-type impurities. In an embodiment, the upper surfaces of the upper drain region 83, the upper gate insulating layer 67 and the first upper insulating layer 74 may form substantially the same plane.

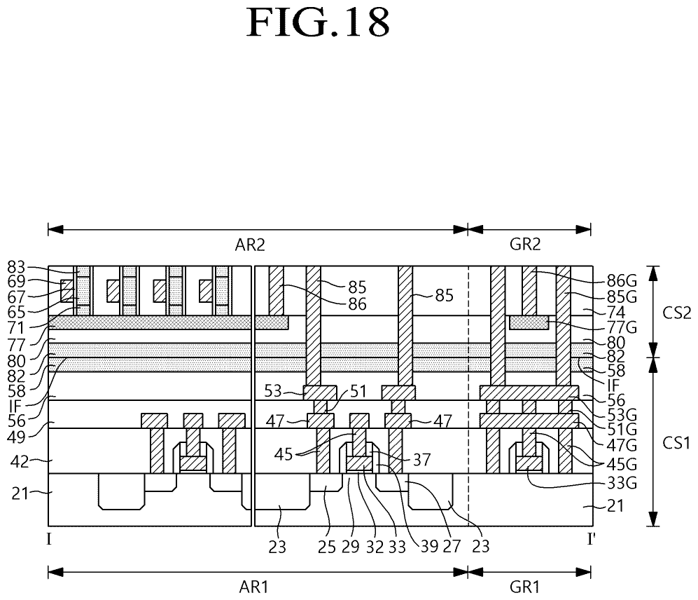

Referring to FIG. 18, a first upper contact plug 85 may be formed in the first and second active regions AR1 and AR2, and a first upper contact guard ring 85G may be formed in the first and second guard ring regions GR1 and GR2. A second upper contact plug 86 may be formed in the second active region AR2, and a second upper contact guard ring 86G may be formed in the second guard ring region GR2. In an embodiment, the first upper contact plug 85, the second upper contact plug 86, the first upper contact guard ring 85G and the second upper contact guard ring 86G may include the same material and may be formed simultaneously.

The first upper contact plug 85 may pass through the first upper insulating layer 74, the second upper insulating layer 80, the upper insulating bonding layer 82, the interface IF, the lower insulating bonding layer 58 and the third lower insulating layer 56 to contact the second lower wiring 53. The second upper contact plug 86 may be formed in the first upper insulating layer 74. The second upper contact plug 86 may pass through the first upper insulating layer 74 to contact the bit line 77.

The first upper contact guard ring 85G may pass through the first upper insulating layer 74, the second upper insulating layer 80, the upper insulating bonding layer 82, the interface IF, the lower insulating bonding layer 58 and the third lower insulating layer 56 to contact the second lower wiring guard ring 53G. The second upper contact guard ring 86G may be formed in the first upper insulating layer 74. The second upper contact guard ring 86G may pass through the first upper insulating layer 74 and contact the bit guard ring 77G.

As illustrated in FIG. 2, a second silicide layer 89 may be formed on the upper drain region 83. Forming the second silicide layer 89 may precede forming the first upper contact plug 85, the second upper contact plug 86, the first upper contact guard ring 85G and the second upper contact guard ring 86G. In an embodiment, after forming the first upper contact plug 85, the second upper contact plug 86, the first upper contact guard ring 85G and the second upper contact guard ring 86G, a process of forming the second silicide layer 89 may be performed. The second silicide layer 89 may include CoSi(cobalt silicide), TiSi(titanium silicide), TaSi(tantalum silicide), NiSi(nickel silicide), WSi(tungsten silicide) or a combination thereof.

Referring again to FIG. 2, a corresponding one 85B of first upper contact barrier layers 85B and 85B′ may contact the upper surface of the corresponding one 53C of the second lower wiring conductive layers 53C and 53C′. The corresponding other one 85B′ of the first upper contact barrier layers 85B and 85B′ may contact the upper surface of the corresponding other one 53C′ of the second lower wiring conductive layers 53C and 53C′. A corresponding one 86B of second upper contact barrier layers 86B and 86B′ may contact the bit barrier layer 77B. The corresponding other one 86B′ of the second upper contact barrier layers 86B and 86B′ may contact the bit barrier layer 77B′. The first upper contact barrier layers 85B and 85B′ and the second upper contact barrier layers 86B and 86B′ may include titanium (Ti), titanium nitride (TiN), tantalum (Ta), tantalum nitride (TaN) or a combination thereof. First upper contact conductive layers 85C and 85C′ and second upper contact conductive layers 86C and 86C′ may include metal, metal nitride, metal oxide, metal silicide, polysilicon, conductive carbon or a combination thereof. In an embodiment, the first upper contact conductive layers 85C and 85C′ and the second upper contact conductive layers 86C and 86C′ may include tungsten (W), tungsten nitride (WN) or a combination thereof.

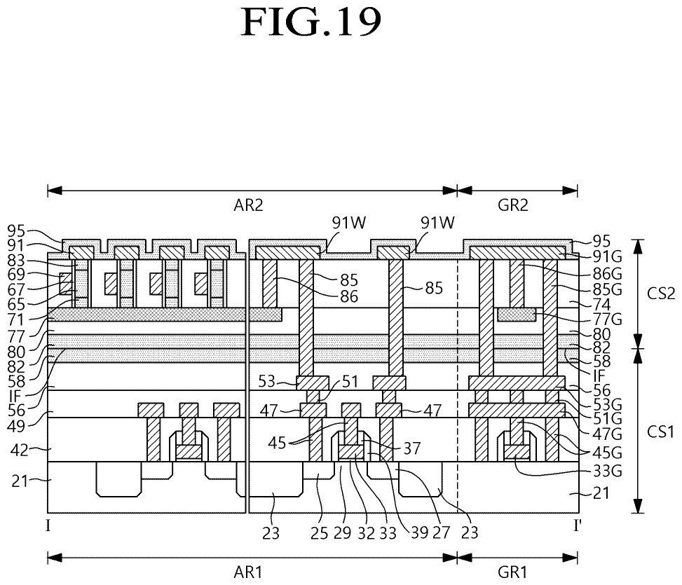

Referring to FIG. 19, a landing pad 91, a first upper wiring 91W and a first upper wiring guard ring 91G may be formed on the first upper insulating layer 74. The landing pad 91, the first upper wiring 91W and the first upper wiring guard ring 91G may include the same material and may be formed simultaneously.

The landing pad 91 may be formed on the upper drain region 83. The landing pad 91 may contact the second silicide layer 89 (see FIG. 2). The landing pad 91 may be connected to the upper drain region 83. The first upper wiring 91W may contact the first upper contact plug 85 and the second upper contact plug 86. The first upper wiring guard ring 91G may contact the first upper contact guard ring 85G and the second upper contact guard ring 86G.

An etch stop layer 95 may be formed on the first upper insulating layer 74. The etch stop layer 95 may cover the first upper insulating layer 74, the landing pad 91, the first upper wiring 91W and the first upper wiring guard ring 91G. The etch stop layer 95 may include nitride such as silicon nitride.

As illustrated in FIG. 2, the landing pad 91, the first upper wiring 91W and the first upper wiring guard ring 91G may include landing pad barrier layers 91B, 91B′ and 91B″ and landing pad conductive layers 91C, 91C′ and 91C″. The landing pad barrier layers 91B, 91B′ and 91B″ may include titanium (Ti), titanium nitride (TiN), tantalum (Ta), tantalum nitride (TaN) or a combination thereof. The landing pad conductive layers 91C, 91C′ and 91C″ may include metal, metal nitride, metal oxide, metal silicide, polysilicon, conductive carbon or a combination thereof. In an embodiment, the landing pad conductive layers 91C, 91C′ and 91C″ may include tungsten (W), tungsten nitride (WN) or a combination thereof.

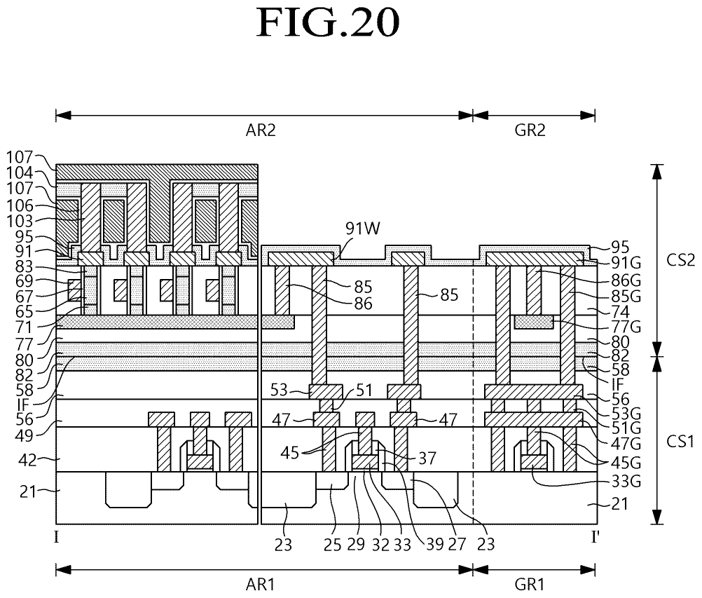

Referring to FIG. 20, a lower electrode 103 may be formed on the landing pad 91. The lower electrode 103 may pass through the etch stop layer 95 to contact the landing pad 91. A support 104 may be formed on the side surface of the lower electrode 103. A capacitor dielectric layer 106 may be formed on the lower electrode 103. The capacitor dielectric layer 106 may cover the lower electrode 103, the etch stop layer 95 and the support 104. An upper electrode 107 may be formed on the capacitor dielectric layer 106.

The lower electrode 103 may include metal, metal nitride, metal oxide, metal silicide, polysilicon, conductive carbon or a combination thereof. In an embodiment, the lower electrode 103 may include titanium (Ti), titanium nitride (TiN), tantalum (Ta), tantalum nitride (TaN), tungsten (W), tungsten nitride (WN) or a combination thereof. The support 104 may include nitride such as silicon nitride. The capacitor dielectric layer 106 may include at least two selected from the group consisting of silicon (Si), oxygen (O), nitrogen (N), carbon (C), boron (B), phosphorus (P) and hydrogen (H). The capacitor dielectric layer 106 may include silicon oxide, silicon nitride, silicon oxynitride, high-k dielectric or a combination thereof. The upper electrode 107 may include metal, metal nitride, metal oxide, metal silicide, polysilicon, conductive carbon or a combination thereof.

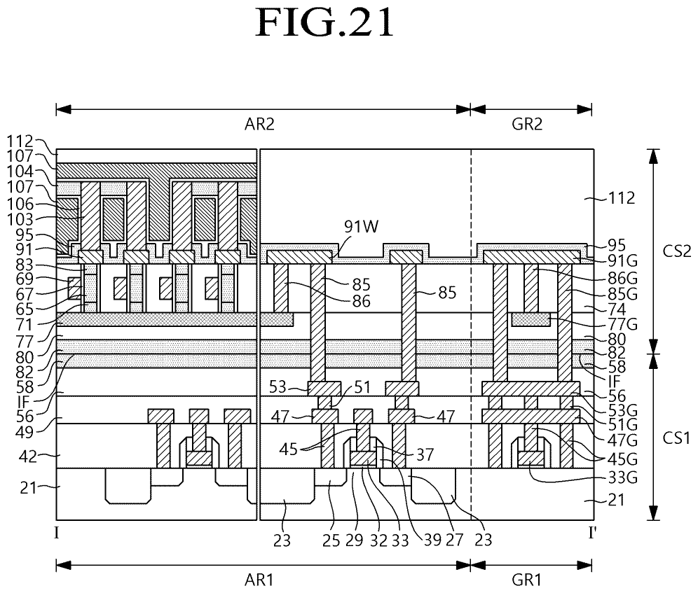

Referring to FIG. 21, a third upper insulating layer 112 may be formed on the etch stop layer 95, the lower electrode 103, the support 104, the capacitor dielectric layer 106 and the upper electrode 107. The third upper insulating layer 112 may include at least two selected from the group consisting of silicon (Si), oxygen (O), nitrogen (N), carbon (C), boron (B), phosphorus (P) and hydrogen (H). The third upper insulating layer 112 may include silicon oxide, silicon nitride, silicon oxynitride, silicon carbide nitride (SiCN), silicon oxycarbon nitride (SiOCN), low-k dielectric, high-k dielectric or a combination thereof.

Referring again to FIG. 1, a third upper contact plug 115 and a third upper contact guard ring 115G may be formed in the third upper insulating layer 112. A selected one of third upper contact plugs 115 may pass through the third upper insulating layer 112 and contact the upper electrode 107. Some of the third upper contact plugs 115 may pass through the third upper insulating layer 112 and the etch stop layer 95 and contact first upper wirings 91W. The third upper contact guard ring 115G may pass through the third upper insulating layer 112 and the etch stop layer 95 and contact the first upper wiring guard ring 91G. The third upper contact plug 115 and the third upper contact guard ring 115G may include the same material and may be formed simultaneously.

As illustrated in FIG. 2, the third upper contact plug 115 and the third upper contact guard ring 115G may include third upper contact barrier layers 115B and 115B′ and third upper contact conductive layers 115C and 115C′. The third upper contact barrier layers 115B and 115B′ may include titanium (Ti), titanium nitride (TiN), tantalum (Ta), tantalum nitride (TaN) or a combination thereof. The third upper contact conductive layers 115C and 115C′ may include metal, metal nitride, metal oxide, metal silicide, polysilicon, conductive carbon or a combination thereof. In an embodiment, the third upper contact conductive layers 115C and 115C′ may include tungsten (W), tungsten nitride (WN) or a combination thereof.

A second upper wiring 117 and a second upper wiring guard ring 117G may be formed on the third upper insulating layer 112. The second upper wiring 117 may contact the third upper contact plug 115. The second upper wiring guard ring 117G may contact the third upper contact guard ring 115G. The second upper wiring 117 and the second upper wiring guard ring 117G may include the same material and may be formed simultaneously. The second upper wiring 117 and the second upper wiring guard ring 117G may include metal, metal nitride, metal oxide, metal silicide, polysilicon, conductive carbon or a combination thereof. In an embodiment, the second upper wiring 117 and the second upper wiring guard ring 117G may include tungsten (W), tungsten nitride (WN), aluminum (Al), copper (Cu), nickel (Ni), cobalt (Co), titanium (Ti), titanium nitride (TiN), tantalum (Ta), tantalum nitride (TaN) or a combination thereof.

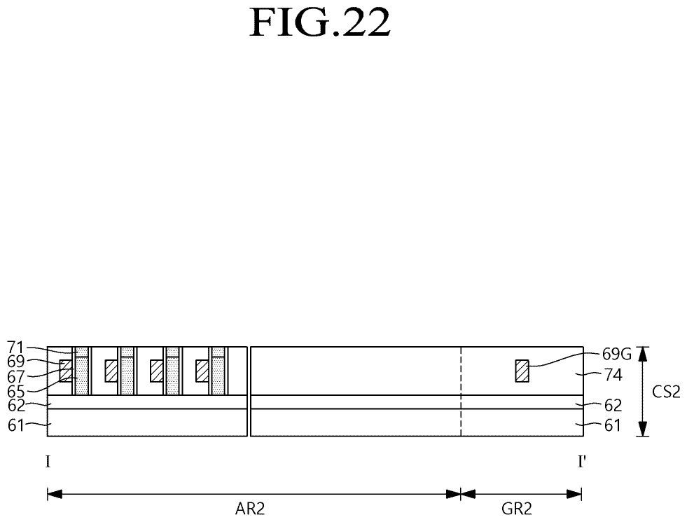

FIG. 22 to FIG. 25 are cross-sectional views for describing a method of forming a semiconductor device according to embodiments of the present disclosure. In an embodiment, FIG. 22 to FIG. 25 may be cross-sectional views taken along the section line I-I′ of FIG. 3.

Referring to FIG. 22, an upper gate guard ring 69G may be formed in the first upper insulating layer 74. The upper gate guard ring 69G may include the same material and may be formed simultaneously with the upper gate electrode 69. The upper gate guard ring 69G may be completely buried in the first upper insulating layer 74.

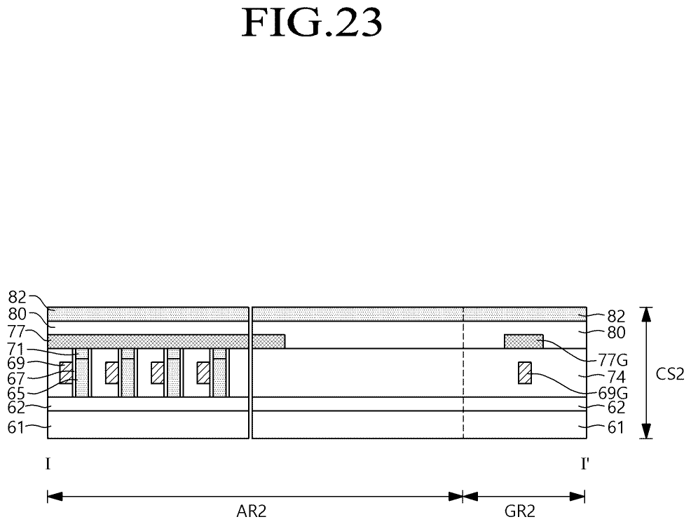

Referring to FIG. 23, a bit line 77, a bit guard ring 77G, a second upper insulating layer 80 and an upper insulating bonding layer 82 may be formed on the first upper insulating layer 74. The bit guard ring 77G may overlap with the upper gate guard ring 69G. The bit guard ring 77G may be spaced apart from the upper gate guard ring 69G. The bit guard ring 77G and the upper gate guard ring 69G may serve to prevent unevenness from occurring on the upper surface of the upper insulating bonding layer 82. In the second active region AR2 and the second guard ring region GR2, the upper surface of the upper insulating bonding layer 82 may have a flat surface.

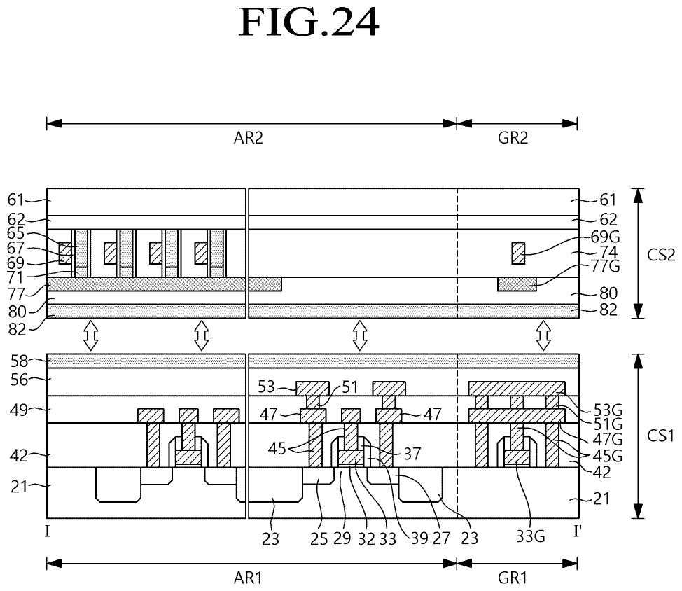

Referring to FIG. 24, a second circuit structure CS2 may be bonded onto a first circuit structure CS1 by bonding the upper insulating bonding layer 82 onto the lower insulating bonding layer 58.

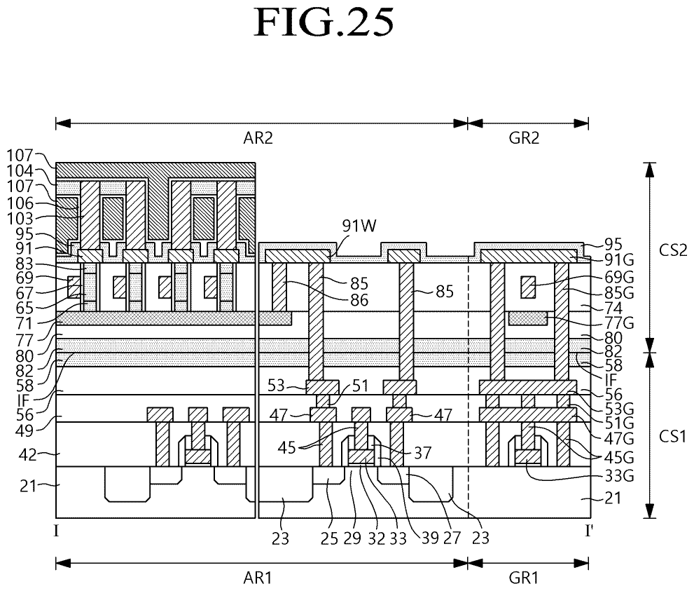

Referring to FIG. 25, the bonding surfaces of the lower insulating bonding layer 58 and the upper insulating bonding layer 82 may have flat surfaces. The upper insulating bonding layer 82 may be densely bonded onto the lower insulating bonding layer 58. For example, the upper insulating bonding layer 82 may be bonded onto the lower insulating bonding layer 58 through fusion bonding. The upper insulating bonding layer 82 and the lower insulating bonding layer 58 are tightly packed together without voids between them. An interface IF may be formed between the lower insulating bonding layer 58 and the upper insulating bonding layer 82. In succession, a semiconductor device may be formed in a similar method as described above with reference to FIG. 5 and FIG. 17 to FIG. 21.

While detailed embodiments are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope. Furthermore, the embodiments may be combined to form additional embodiments.

What is claimed is:

1. A semiconductor device comprising:
a first circuit structure and a second circuit structure bonded together, the first circuit structure including a first active region and a first guard ring region, and the second circuit structure including a second active region and a second guard ring region;
a first upper contact plug disposed in the first active region and the second active region, and passing through an interface between the first circuit structure and the second circuit structure; and
a first upper contact guard ring disposed in the first guard ring region and the second guard ring region, and passing through the interface,
wherein the second circuit structure comprises:
a bit line in the second active region; and
a bit guard ring disposed in the second guard ring region and at substantially the same level as the bit line.

2. The semiconductor device according to claim 1, wherein a distance between the lowermost surface of the bit guard ring and the interface is substantially the same as a distance between the lowermost surface of the bit line and the interface.

3. The semiconductor device according to claim 1, wherein the bit guard ring has substantially the same thickness as the bit line.

4. The semiconductor device according to claim 1, wherein the bit guard ring includes the same material as the bit line.

5. The semiconductor device according to claim 1, wherein the first upper contact guard ring is disposed at substantially the same level as the first upper contact plug.

6. The semiconductor device according to claim 1, wherein the first upper contact guard ring has substantially the same thickness as the first upper contact plug.

7. The semiconductor device according to claim 1,
wherein the first circuit structure comprises:
a first lower insulating layer on a substrate;
a lower gate electrode in the first lower insulating layer;
a second lower insulating layer on the first lower insulating layer;
a lower insulating bonding layer on the second lower insulating layer;
a lower wiring disposed in the second lower insulating layer in the first active region; and
a lower wiring guard ring disposed in the second lower insulating layer in the first guard ring region, and
wherein the second circuit structure comprises:
an upper insulating bonding layer bonded onto the lower insulating bonding layer;
a first upper insulating layer on the upper insulating bonding layer;
a second upper insulating layer between the upper insulating bonding layer and the first upper insulating layer, the bit line and the bit guard ring being disposed in the second upper insulating layer;
an upper channel disposed in the first upper insulating layer, and disposed on the bit line; and
an upper gate electrode disposed in the first upper insulating layer, and spaced apart from the upper channel.

8. The semiconductor device according to claim 7, wherein
the first upper contact plug passes through the first upper insulating layer, the second upper insulating layer, the upper insulating bonding layer, the interface, the lower insulating bonding layer and the second lower insulating layer to contact the lower wiring, and
the first upper contact guard ring passes through the first upper insulating layer, the second upper insulating layer, the upper insulating bonding layer, the interface, the lower insulating bonding layer and the second lower insulating layer to contact the lower wiring guard ring.

9. The semiconductor device according to claim 7,
wherein the second circuit structure further comprises:
a landing pad, an upper wiring and an upper wiring guard ring on the first upper insulating layer,
wherein the landing pad is connected to the upper channel,
wherein the upper wiring contacts the first upper contact plug, and
wherein the upper wiring guard ring contacts the first upper contact guard ring.

10. The semiconductor device according to claim 9, wherein the upper wiring guard ring is disposed at substantially the same level as the landing pad or the upper wiring.

11. The semiconductor device according to claim 9, wherein the upper wiring guard ring has substantially the same thickness as the landing pad or the upper wiring.

12. The semiconductor device according to claim 7, wherein the second circuit structure further comprises:
a second upper contact plug passing through the first upper insulating layer in the second active region, and contacting the bit line; and
a second upper contact guard ring passing through the first upper insulating layer in the second guard ring region, and contacting the bit guard ring.

13. The semiconductor device according to claim 12, wherein the second upper contact guard ring is disposed at substantially the same level as the second upper contact plug.

14. The semiconductor device according to claim 12, wherein the second upper contact guard ring has substantially the same thickness as the second upper contact plug.

15. The semiconductor device according to claim 12, wherein:
each of the bit line and the bit guard ring includes a bit barrier layer and a bit conductive layer on the bit barrier layer,
each of the second upper contact plug and the second upper contact guard ring includes an upper contact barrier layer and an upper contact conductive layer on the upper contact barrier layer,
the bit barrier layer of the bit line contacts the upper contact barrier layer of the second upper contact plug, and
the bit barrier layer of the bit guard ring contacts the upper contact barrier layer of the second upper contact guard ring.

16. The semiconductor device according to claim 15, wherein the bit barrier layer and the upper contact barrier layer include titanium (Ti), titanium nitride (TiN), tantalum (Ta), tantalum nitride (TaN) or a combination thereof.

17. The semiconductor device according to claim 7, further comprising:
an upper gate guard ring disposed in the first upper insulating layer in the second guard ring region and at substantially the same level as the upper gate electrode.

18. The semiconductor device according to claim 17, wherein the upper gate guard ring has substantially the same thickness as the upper gate electrode.

19. A semiconductor device comprising:
a substrate disposed in a first active region and a first guard ring region;
a lower insulating layer disposed on the substrate;
a lower gate electrode disposed in the lower insulating layer;
a lower wiring disposed in the lower insulating layer in the first active region;
a lower wiring guard ring disposed in the lower insulating layer in the first guard ring region;
a lower insulating bonding layer disposed on the lower insulating layer;
an upper insulating bonding layer bonded onto the lower insulating bonding layer;
a first upper insulating layer on the upper insulating bonding layer;
a second upper insulating layer disposed between the upper insulating bonding layer and the first upper insulating layer;
a bit line disposed in the second upper insulating layer in a second active region;
a bit guard ring disposed in the second upper insulating layer in a second guard ring region, the bit guard ring being disposed at substantially the same level as the bit line;
a first upper contact plug passing through the first upper insulating layer, the second upper insulating layer, the upper insulating bonding layer, the lower insulating bonding layer and the lower insulating layer to contact the lower wiring;
a first upper contact guard ring passing through the first upper insulating layer, the second upper insulating layer, the upper insulating bonding layer, the lower insulating bonding layer and the lower insulating layer to contact the lower wiring guard ring;
an upper channel disposed in the first upper insulating layer in the second active region, and disposed on the bit line;
an upper gate electrode disposed in the first upper insulating layer in the second active region, and spaced apart from the upper channel;
a landing pad disposed on the first upper insulating layer, and connected to the upper channel;
a lower electrode disposed on the landing pad;
a capacitor dielectric layer disposed on the lower electrode; and
an upper electrode disposed on the capacitor dielectric layer.

20. A semiconductor device comprising:
a first circuit structure including a first active region and a first guard ring region; and
a second circuit structure including a second active region and a second guard ring region,
wherein the second circuit structure is bonded onto the first circuit structure, and
wherein the second circuit structure comprises:
a bit line in the second active region; and
a bit guard ring disposed in the second guard ring region and at substantially the same level as the bit line.
